(19) United States
(12) Patent Application Publication
(10) Pub. No.: US 2025/0006812 A1
(43) Pub. Date: Jan. 2, 2025

(54) N-TYPE TRANSISTOR FABRICATION IN COMPLEMENTARY FET (CFET) DEVICES

(71) Applicant: INTEL CORPORATION, SANTA CLARA, CA (US)

(72) Inventors: Sudipto Naskar, Portland, OR (US); Sukru Yemenicioglu, Portland, OR (US); Abhishek Anil Sharma, Portland, OR (US); Van Le, Beaverton, OR (US); Weimin Han, Portland, OR (US)

(73) Assignee: INTEL CORPORATION, SANTA CLARA, CA (US)

(21) Appl. No.: 18/346,106

(22) Filed: Jun. 30, 2023

(51) Int. Cl. H01L 29/423; H01L 21/8238; H01L 27/092; H01L 29/06; H01L 29/08; H01L 29/66; H01L 29/775; H01L 29/78; H01L 29/786

(52) U.S. Cl. CPC H01L 29/42392; H01L 21/823821; H01L 27/0924; H01L 29/0673; H01L 29/0847; H01L 29/66439; H01L 29/66795; H01L 29/775; H01L 29/7851; H01L 29/78696

(57) ABSTRACT

N-type gate-all-around (nanosheet, nanoribbon, nanowire) field-effect transistors (GAAFETs) vertically stacked on top of p-type GAAFETs in complementary FET (CFET) devices comprise non-crystalline silicon layers that form the n-type transistor source, drain, and channel regions. The non-crystalline silicon layers can be formed via deposition, which can provide for a simplified processing flow to form the middle dielectric layer between the n-type and p-type GAAFETs relative to processing flows where the silicon layers forming the n-type transistor source, drain, and channel regions are grown epitaxially.

### BACKGROUND

In some proposed complementary field-effect transistor (CFET) devices, an n-type gate-all-around (nanoribbon, nanosheet, nanowire) field-effect transistor (GAAFET) is vertically stacked with a p-type GAAFET. The vertical stacking of n-type and p-type GAAFETs in CFET devices can allow for increased transistor packing density in the x- and y-dimensions.

### BRIEF DESCRIPTION OF THE DRAWINGS

FIGS. 1A-1C are cross-sectional views of example CFET devices comprising HPTFT materials.

FIGS. 2 through 7A-7C illustrate an example simplified process sequence for forming the example CFETs structures comprising HPTFT materials illustrated in FIGS. 1A-1C.

FIG. 8 is an example method of forming a CFET device with HPTFT materials.

FIG. 9 is a top view of a wafer and dies that may be included in a microelectronic assembly, in accordance with any of the embodiments disclosed herein.

FIG. 10 is a cross-sectional side view of an integrated circuit device that may be included in a microelectronic assembly disclosed herein.

FIGS. 11A-11D are perspective views of example planar, FinFET, gate-all-around, and stacked gate-all-around transistors.

FIGS. 12A and 12B are perspective and cross-sectional views of example forksheet gate-all-around transistors.

FIGS. 13A and 13B are perspective and cross-sectional views of an example complementary field-effect-transistor (CFET) architecture.

FIG. 14 is a cross-sectional side view of an integrated circuit device assembly that may include one or more of the microelectronic assemblies disclosed herein.

FIG. 15 is a block diagram of an example electrical device that may include a microelectronic assembly, in accordance with any of the embodiments disclosed herein.

### DETAILED DESCRIPTION

Complementary field effect transistor (CFET) devices are being considered to help enable the continuing scaling of transistor packing density in future semiconductor manufacturing technology nodes. In CFET devices, an n-type gate-all-around FET (GAAFET) is vertically stacked with a p-type GAAFET. The integration of monolithic CFET device formation (in which both the n-type and p-type GAAFETs are formed on the same substrate) into semiconductor manufacturing processes presents difficult challenges. One challenge is to integrate a middle dielectric layer that is positioned between the p-type and n-type GAAFETs. In some proposed CFET processing flows, the formation of a middle dielectric layer begins with the formation of a sacrificial layer on the p-type GAAFET. The sacrificial layer acts as a seed layer for the epitaxial growth of silicon-based source, drain, and channel regions of the n-type GAAFET and intervening sacrificial layers. The sacrificial layer and intervening sacrificial layers can comprise, for example, silicon germanium. The sacrificial layer is eventually removed via etching and the resulting void is backfilled with dielectric material to create the middle dielectric layer. The formation of the middle dielectric layer in such processes can present challenges. For example, the sacrificial layer is to be removed from a trench without impacting the channel regions of the n-type and p-type GAAFETs above and below the sacrificial layer.

Disclosed herein are CFET devices that can be formed using high-performance thin-film transistor (HPTFT) materials for the source, drain, and channel regions for an n-type GAAFET in CFET devices where the n-type GAAFET is stacked atop a p-type GAAFET. These HPTFT materials comprising non-crystalline silicon can be formed via deposition. The as-deposited HPTFT layers can form the n-type GAAFET source, drain, and channel regions, or these regions can be formed by patterning a deposited HPTFT layer. These non-crystalline silicon HPTFT materials are back-end-of-line (BEOL) compatible. The use of non-crystalline silicon for the n-type GAAFET source, drain, and channel regions can provide for process simplicity over the sacrificial layer approach in generating a middle dielectric layer described above. Nanoribbons of non-crystalline silicon form the n-type transistor source, drain, and channel regions and the sacrificial dielectric layers formed between the nanoribbons during GAAFET formation can be formed via deposition instead of being grown epitaxially, which requires the growth of a sacrificial layer to function as the seed layer for the epitaxially-grown films, and subsequent removal of the sacrificial layer and backfilling with the desired dielectric material to form the middle dielectric layer.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact with each other and “coupled” may indicate elements co-operate or interact with each other, but they may or may not be in direct physical or electrical contact. Furthermore, the terms “comprising,” “including,” “having,” and the like, as used with respect to embodiments of the present disclosure, are synonymous.

Terms modified by the word “substantially” include arrangements, orientations, spacings, or positions that vary slightly from the meaning of the unmodified term. For example, the portion of a first layer or feature that is substantially perpendicular to a second layer or feature can include a first layer or feature that is +/−20 degrees from a second layer or feature, a first surface that is substantially parallel to a second surface can include a first surface that is within several degrees of parallel from the second surface, and a layer that is substantially planar can include layers that comprise some dishing, bumps, or other non-planar features resulting from processing variations and/or limitations.

As used herein, the phrase “positioned between” in the context of a first layer or component positioned between a second layer or component and a third layer or component refers to the first layer or component being directly physically attached to the second and third parts or components (no layers or components between the first and second layers or components or the first and third layers or components) or physically attached to the second and third layers or components with one or more intervening layers or components.

As used herein, the term “adjacent” refers to layers or components that are in physical contact with each other. That is, there is no layer or component between the stated adjacent layers or components. For example, a layer X that is positioned adjacent to a layer Y refers to a layer that is in physical contact with layer Y.

Certain terminology may also be used herein for the purpose of reference only, and thus are not intended to be limiting. For example, terms such as “upper,” “lower,” “above,” “below,” “bottom,” “top”, “lateral” and “vertical” refer to directions in the Figures to which reference is made. Terms such as “front,” “back,” “rear,” and “side” describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

As used herein, the term “integrated circuit component” refers to a packaged or unpackaged integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well known structures and devices are shown in block diagram form in order to facilitate a description thereof. The intention is to cover all modifications, equivalents, and alternatives within the scope of the claims.

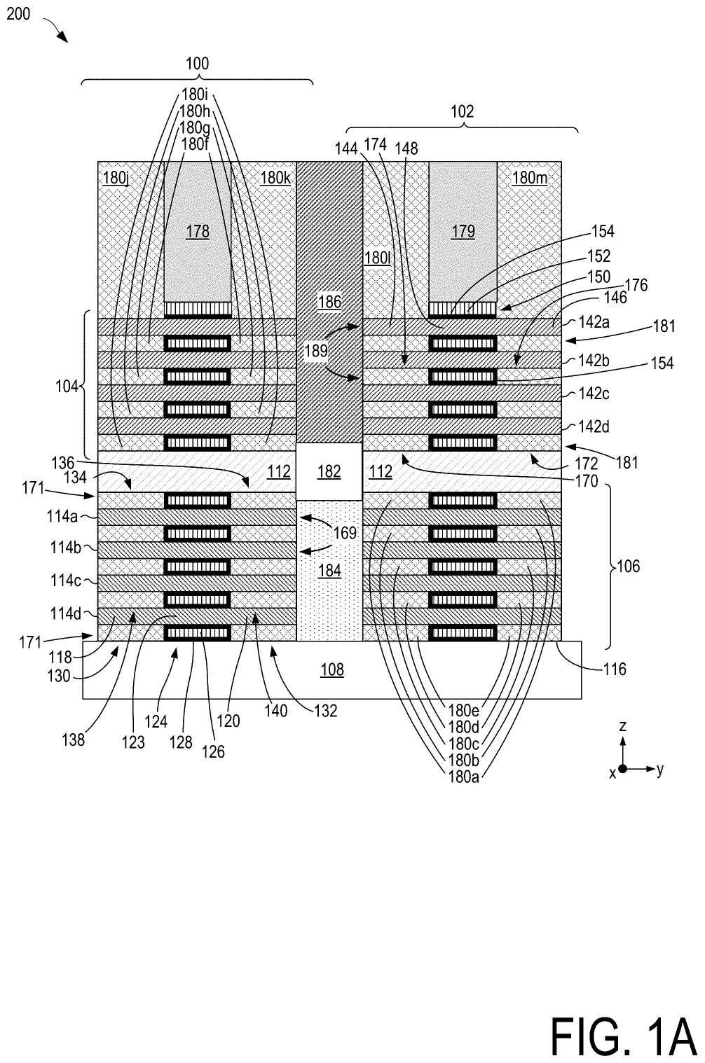

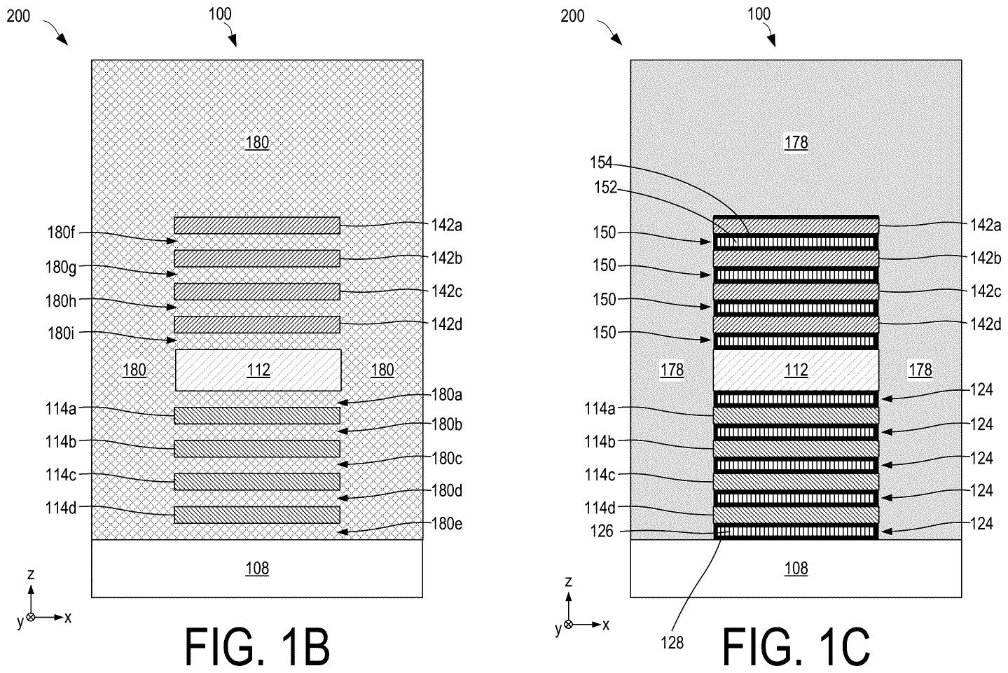

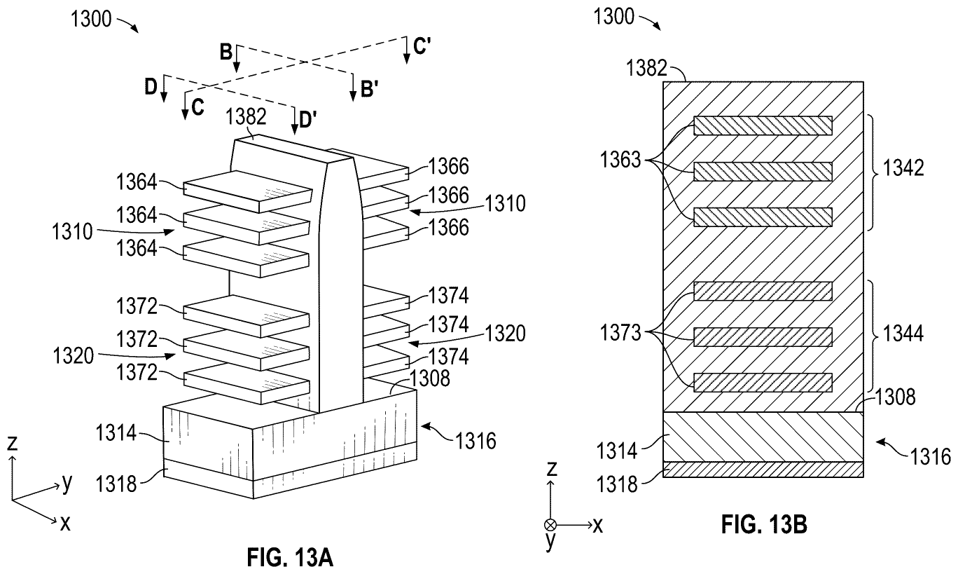

FIGS. 1A-1C are cross-sectional views of example CFET devices comprising HPTFT materials. FIG. 1A illustrates a cross-sectional view of a structure 200 comprising adjacent CFET devices 100 and 102, which are similar to CFET device 1300 illustrated in FIG. 13A. The cross-sectional view of FIG. 1A is taken along a line extending through the source, drain, and gate regions of CFET devices 100 and 102 and is similar to a cross-sectional view of CFET device 1300 taken along the line C-C′ in FIG. 13A. The cross-sectional view of FIG. 1B is taken along a line extending through a source or drain region of CFET device 100 and is similar to a cross-sectional view of CFET device 1300 taken along the line D-D′ in FIG. 13A. The cross-sectional view of FIG. 1C is taken along a line extending through the gate region of CFET device 100 and is similar to a cross-sectional view taken along the line B-B′ of CFET device 1300 in FIG. 13A.

Each of the CFET devices 100 and 102 comprise an n-type GAAFET 104 and a p-type GAAFET 106 stacked vertically over a substrate 108, with the n-type GAAFET 104 located over the p-type GAAFET 106. A middle dielectric layer 112 is positioned between the GAAFETs 104 and 106 to isolate the GAAFETs 104 and 106 from each other. Each p-type GAAFET 106 comprises nanoribbons (layers, nanosheets, nanowires) 114 (114a-114d) that are stacked vertically with respect to a surface 116 of the substrate 108. The nanoribbons 114 are substantially planar and substantially parallel to each other. Each nanoribbon 114 comprises silicon and comprises a p-type source region 118, a p-type drain region 120, and a channel region 123 positioned laterally between the p-type source and drain regions 118 and 120. The p-type source and drain regions 118 and 120 comprise a p-type dopant. The channel regions 123 are further positioned vertically between two gate regions 124. Each gate region 124 comprises a gate dielectric layer 128 encircling a gate electrode 126. The p-type drain regions 120 are conductively coupled via ends 169 of the p-type drain regions 120 being positioned adjacent to a first source or drain contact region. The p-type source regions 118 are conductively coupled via ends 171 of the p-type source regions 118 being positioned adjacent to a second source or drain contact region (not shown in FIG. 1A). The first source or drain contact region is also not illustrated in FIGS. 1A and 1s positioned adjacent to a region 184, which can comprise a conductive material (such as n-doped silicon), along a first distance on the x-axis different from a second distance along the x-axis where the third and fourth drain or source contact regions (discussed below) are located (such as the point along the x-axis where the cross-sectional view of FIG. 1A is taken). This is because the first and second source or drain contact regions need to extend through n-type GAAFET to reach the source and drain regions of the p-type GAAFET 106.

Each p-type GAAFET 106 further comprises a plurality of spacer regions 180a-180e that are stacked vertically with respect to the substrate surface 116, substantially planar, and substantially parallel with each other. The spacer regions 180a-180e isolate the gate regions 124 from source or drain contacts. A bottommost spacer region 180e (the spacer region 122 nearest to the substrate 108) is positioned between a portion of the bottommost nanoribbon 114d (the nanoribbon 114 nearest to the substrate 108) and the substrate surface 116. A first portion 130 of the bottommost spacer region 180e is positioned between a p-type source region 118 of the bottommost nanoribbon 114d and the substrate 108 and a second portion 132 of the bottommost spacer region 180e is positioned between the p-type drain region 120 of the bottommost nanoribbon 114d and the substrate 108. A topmost spacer region 180a (the spacer region 122 nearest to the middle dielectric layer 112) is positioned between a portion of the topmost nanoribbon 114a (the nanoribbon 114 nearest to the middle dielectric layer 112) and the middle dielectric layer 112. A first portion 134 of the topmost spacer region 180a is positioned between the p-type source region 118 of the topmost nanoribbon 114a and the middle dielectric layer 112 and a second portion 136 of the topmost spacer region 180a is positioned between the p-type drain region 120 of the topmost nanoribbon 114a and the middle dielectric layer 112. For each of the spacer regions 180b, 180c, and 180d, a first portion 138 of these spacer regions is positioned adjacent to at least a portion of the p-type source regions 118 of two of the nanoribbons 114, and a second portion 140 of these spacer regions is positioned adjacent to at least a portion of the p-type drain regions 120 of two of the nanoribbons 114. Described another way, first and second portions of each of the spacer regions 180a-180e are located on either side of a gate region 124.

Each n-type GAAFET 104 comprises four nanoribbons 142 (142a-142d) that are stacked vertically with respect to the substrate surface 116. The nanoribbons 142 are substantially planar and substantially parallel to each other. Each nanoribbon 142 comprises silicon and comprises an n-type source region 144, an n-type drain region 146, and a channel region 148 positioned laterally between the n-type source and drain regions 144 and 146. The channel regions 148 are further positioned vertically between two gate regions 150. Each gate region 150 comprises a gate dielectric layer 154 and a gate electrode 152. For the topmost gate region 150 (the gate region furthest from the substrate 108), the gate dielectric layer 154 is positioned between the gate electrode 152 and the topmost channel region 148. For the other gate regions 150, the gate dielectric layer 154 encircles the gate electrode 152. In some embodiments, the topmost gate region may not comprise a gate electrode 152 and the topmost gate dielectric region may be positioned adjacent to a gate contact region (e.g., 178, 179). The gate regions 150 and 124 of the CFET devices 100 and 102 are conductively coupled by gate contact regions 178 and 179, respectively. A portion of the gate contact regions 178 and 179 is positioned adjacent to nanoribbon 142a, the nanoribbon 142 positioned furthest away from the middle dielectric layer 112. The n-type source regions 144 are conductively coupled via ends 189 of the n-type source regions 144 being positioned adjacent to a third source or drain contact region 186 and the n-type drain regions 146 are conductively coupled via ends 181 of the n-type source regions being positioned adjacent to a fourth source or drain contact region (not shown in FIG. 1A). A dielectric region 182 is located between the third source or drain contact region 186 and the region 184 (which can comprise epitaxially-grown n-doped silicon).

Each n-type GAAFET 104 further comprises a plurality of spacer regions 180f-180i that are stacked vertically with respect to the substrate surface 116, substantially planar, and substantially parallel with each other. A bottommost spacer region 180i (the spacer region 168 positioned nearest to the middle dielectric layer 112) is positioned between a portion of the bottommost nanoribbon 142d (the nanoribbon 142 positioned nearest to the middle dielectric layer 112) and the middle dielectric layer 112. A first portion 170 of the bottommost spacer region 180i is positioned between an n-type source region 144 of the bottommost nanoribbon 142d and the middle dielectric layer 112 and a second portion 172 of the bottommost spacer region 180i is positioned between the n-type source region 146 of the bottommost nanoribbon 142d and the middle dielectric layer 112. For each of the spacer regions 180f, 180g, and 180h, a first portion 174 of these spacer regions is positioned adjacent to at least a portion of the n-type source regions 144 of two of the nanoribbons 142 and a second portion 176 of these spacer regions is positioned adjacent to at least a portion of the n-type drain regions 146 of two of the nanoribbons 142. Described another way, the first and second portions of each of the spacer regions 180f-180i are located on either side of a gate region 150. Spacer regions 180j-m to separate the gate contact regions 178 and 179 from source or drain contacts (e.g., 186) are positioned adjacent to the gate contact regions 178 and 179.

The nanoribbons 142 that form the source, drain, and channel regions of the n-type GAAFET 106 comprise non-crystalline silicon, an HPTFT material. The non-crystalline silicon can comprise amorphous and/or polycrystalline silicon. The n-type source and drain regions 144 and 146 of the nanoribbons 142 of the n-type GAAFETs 104 comprise an n-type dopant, such as phosphorous, arsenic, antimony, or another suitable n-type silicon dopant. The p-type source and drain regions 118 and 120 of the nanoribbons 114 of the p-type GAAFETs 106 comprise a p-type dopant, such as boron, gallium, or any other suitable p-type silicon dopant.

The dielectric regions 180a-180c, 142a-142d, 180, and 182 can comprise a suitable nitride or oxide, such as silicon nitride (Si₃N₄), silicon dioxide (SiO₂), carbon-doped silicon dioxide (C-doped SiO₂, also known as CDO or organosilicate glass, which is a material that comprises silicon, oxygen, and carbon), fluorine-doped silicon dioxide (F-doped SiO₂, also known as fluorosilicate glass, which is a material that comprises fluorine, silicon, and oxygen), hydrogen-doped silicon dioxide (H-doped SiO₂, which is a material that comprises silicon, oxygen, and hydrogen).

The gate dielectric layers 128 and 154 can comprise one or more layers comprising any of the materials that can be part of any gate dielectric layer described or referenced herein, such as the gate dielectric of gate 1122. The gate dielectric layers 128 can comprise the same or different materials as the dielectric layers 154. The gate electrodes 126 for the p-type GAAFETs 106 can comprise any material that can be part of any gate electrode for a p-type transistor described herein, such as the gate dielectric of gate 1022 for a p-type (PMOS) transistor. The gate electrodes 152 for the n-type GAAFETs 104 can comprise any material that can be part of any gate electrode for an n-type transistor described herein, such as the gate dielectric of gate 1022 for an n-type (NMOS) transistor.

The first, second, third, and fourth source or drain contacts (e.g., 186) and the gate contact regions 178 and 179 can comprise one or more metal layers. In some embodiments, these source, drain, and gate contacts can comprise a fill (trench, plug) layer that comprises tungsten, cobalt, titanium, gold, aluminum, molybdenum, chromium, nickel, or other suitable metal. The source, drain, and gate contacts disclosed herein can comprise one or more additional metal layers for other purposes, such as one or more barrier layers positioned between a fill metal layer and a source or drain region, and a contact metal layer positioned adjacent to a source or drain region. A barrier layer can reduce the amount of metal that diffuses from the fill metal layer to a source or drain region and/or prevent or reduce oxidation of a contact metal layer between formation of the contact metal layer and formation of the fill metal layer. A barrier layer can comprise cobalt (Co), ruthenium (Ru), tantalum (Ta), tantalum nitride (which is a material comprising titanium and nitrogen (e.g., TaN, Ta₂N, Ta₃N₅)), indium oxide (In₂O₃, which is a material that comprises indium and oxygen), tungsten nitride (which is a material that comprises tungsten and nitrogen (e.g., W₂N, WN, WN₂), titanium nitride (TiN, which is a material that comprises titanium and nitrogen), or other suitable material. A contact metal layer can comprise titanium, tantalum, hafnium, zirconium, niobium, or other suitable metal. The substrate 108 can comprise any of the materials that can be part of any substrate described or referenced herein, such as die substrate 1002.

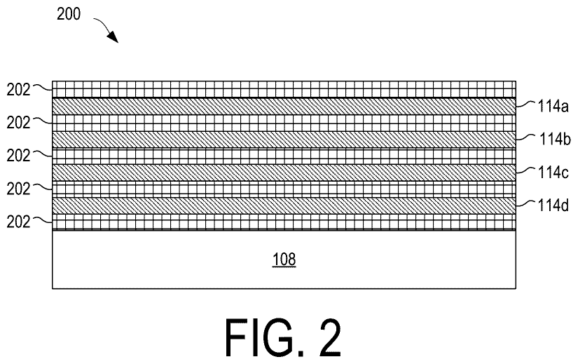

FIGS. 2 through 7A-7C illustrate an example simplified process sequence for forming the example CFETs structures comprising HPTFT materials illustrated in FIGS. 1A-1C.

FIG. 2 is a cross-sectional view of an example structure 200 after formation of vertically stacked first sacrificial layers 202 interleaved with the first layers 114 on the substrate 108. The substrate 108 can comprise silicon and the first sacrificial layers 202 can comprise silicon germanium. The first layers 114 and the first sacrificial layers 202 can be epitaxially grown. The first layers 114 comprise silicon and a p-type dopant, which can be incorporated into the first layers during or after (e.g., via an implantation step) epitaxial growth.

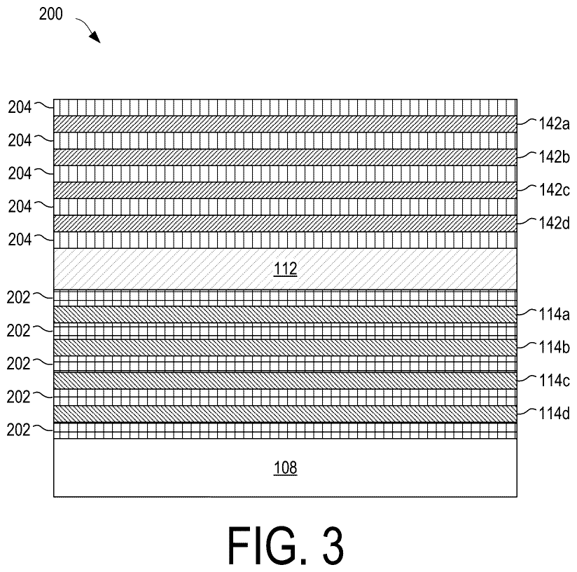

FIG. 3 is a cross-sectional view of the structure 200 after formation of the middle dielectric layer 112, the second layers 142, and second sacrificial layers 204. The middle dielectric layer 112 is formed on the topmost first sacrificial layer 202. The second layers 142 are interleaved with the second sacrificial layers. The second sacrificial layers 204 comprise a dielectric (such as an oxide and nitride dielectric). The second layers 142 comprise non-crystalline silicon. The second layers 142 and the second sacrificial layers 204 are formed via deposition. The second sacrificial layer 204 located nearest the middle dielectric layer 112 are deposited on the middle dielectric layer 112 and each of the second layers 142 are deposited on one of the second sacrificial layer 204. As already mentioned, the ability to form via deposition the silicon layers (second layers 142a-142d) that become the source, drain, and channel regions of the n-type GAAFET in a CFET structure can provide for processing advantages over processes the grow the second layers 142 epitaxially. The second layers 142 comprise an n-type dopant, which can be incorporated into the first layers during or after epitaxial growth of the second layers 142.

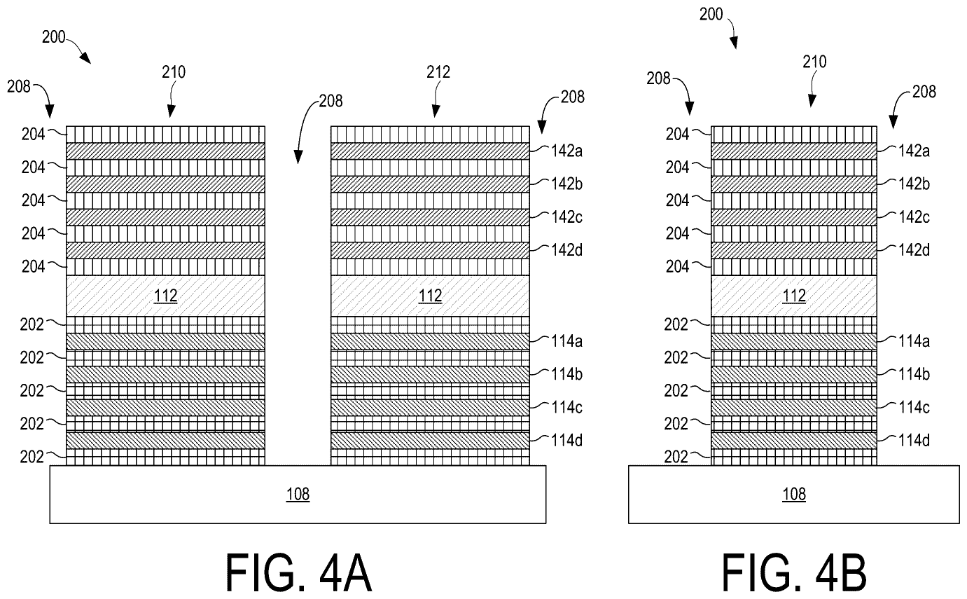

FIGS. 4A and 4B illustrate cross-sectional views of the structure 200 after forming trenches 208 via etching to create pillars 210 and 212 that will eventually become CFET devices 100 and 102. In FIGS. 4A-4B, 5A-5C, 6A-6C, and 7A-7C, the “A”, “B”, and “C” Figures are cross-sectional views of the structure 200 taken along lines similar to those associated with the cross-sectional views of FIGS. 1A, 1B, and 1C, respectively.

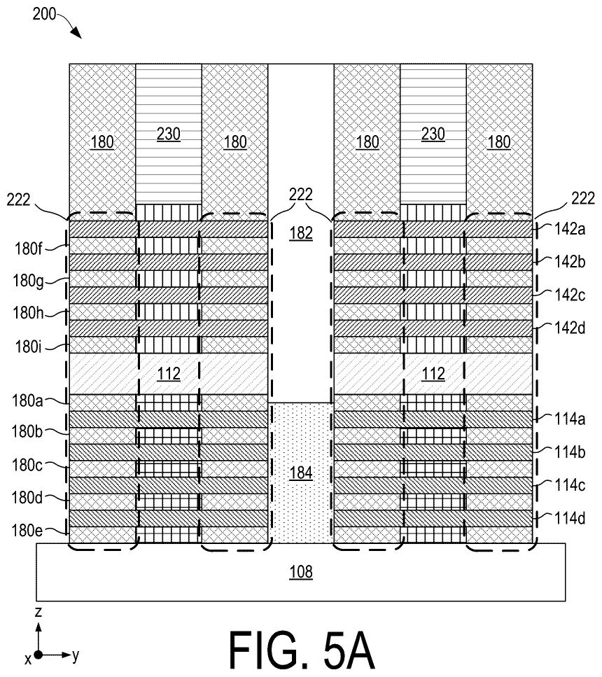

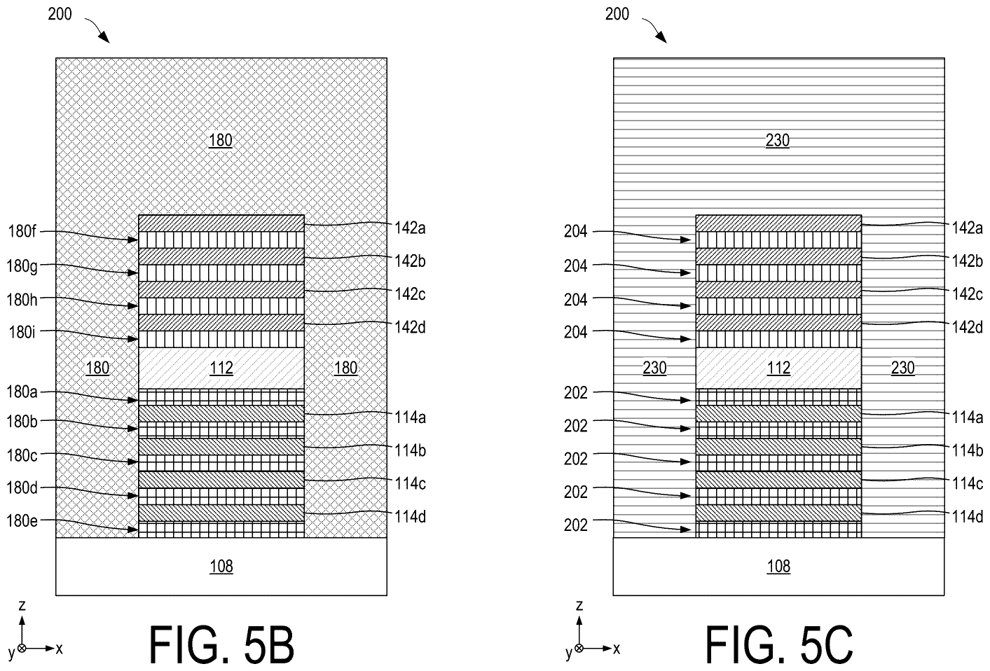

FIGS. 5A-5C illustrate cross-sectional views of the structure 200 after removal of the first and second sacrificial layers 202 and 204 in the source and drain regions 222 and backfill with spacer layers 180a-180e and 180f-180i, formation of the region 184, formation of dummy gate regions 230, and formation of dielectric regions 180j-m and 182.

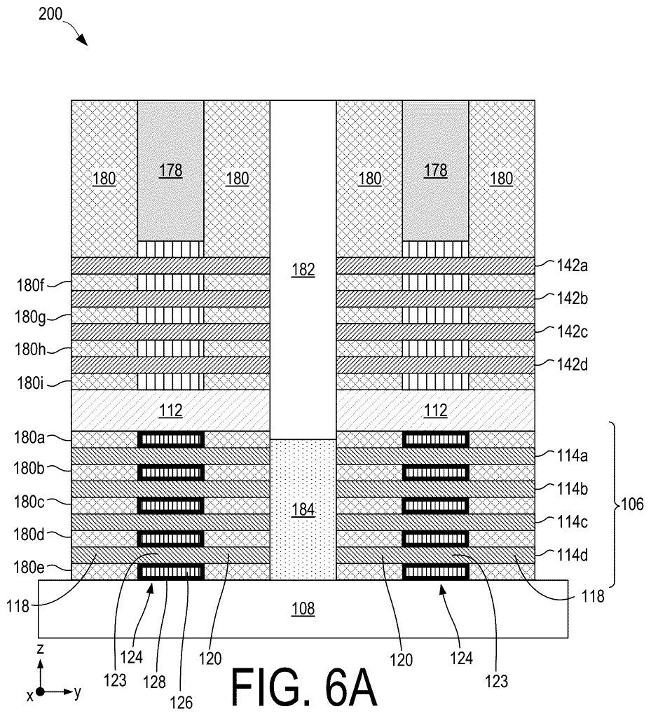

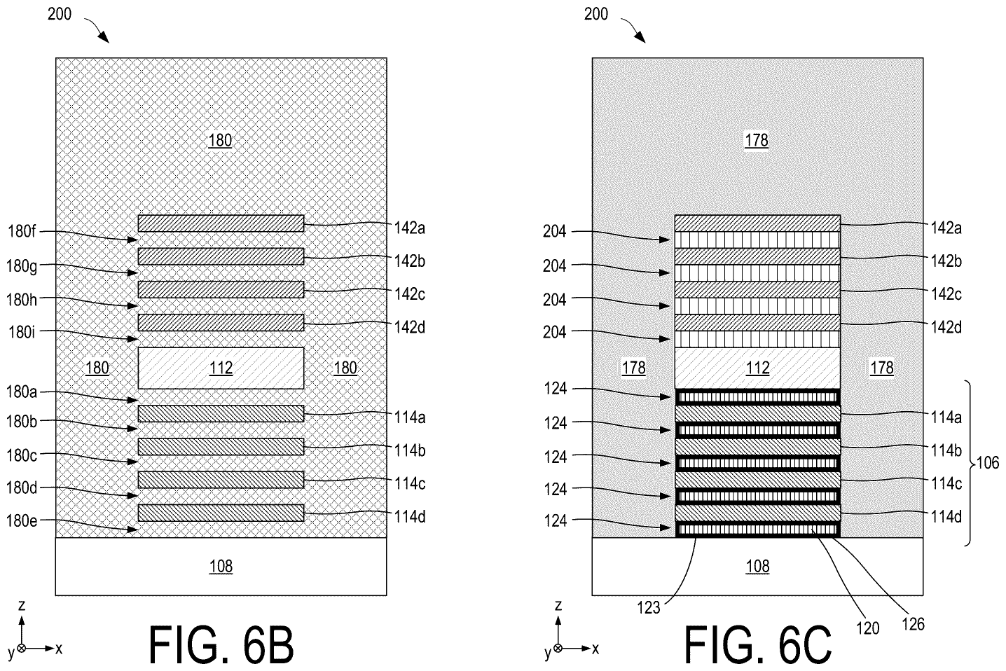

FIGS. 6A-6C illustrate cross-sectional views of the structure 200 after removal of the dummy gate 230 and formation of the gate regions 124 of the p-type GAAFET 106. Each of the gate regions 124 of the p-type GAAFETs comprises a gate dielectric layer 128 encircling a gate electrode 126. Each of the nanoribbons 114a-114d comprises a p-type source region 118, a p-type drain region 120, and a channel region 123. Each channel region 123 is positioned vertically between two gate regions 124 and positioned laterally between a p-type source region 118 and a p-type drain region 120.

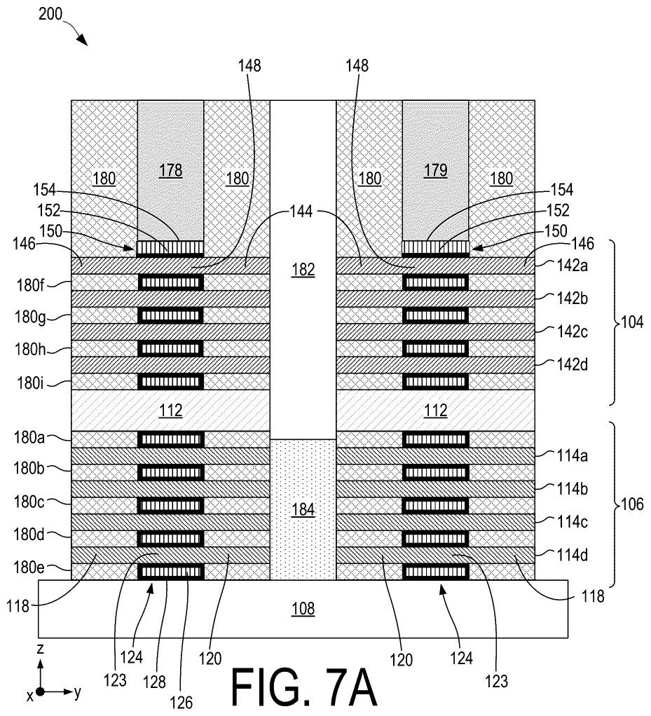

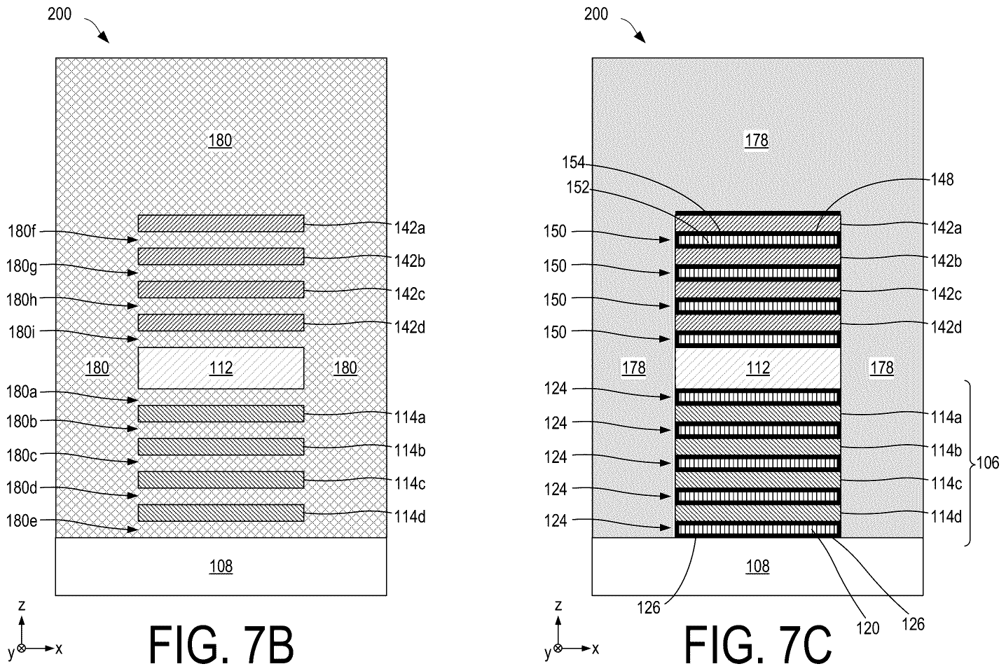

FIGS. 7A-7C illustrate cross-sectional views of the structure 200 after formation of the gate regions 150 of the n-type GAAFETs 106 and the gate contact regions 178 and 179. Each of the gate regions 150 of the n-type GAAFETs comprise a gate dielectric layer 154 encircling a gate electrode 152. Each of the nanoribbons 142a-142d comprises an n-type source region 144. an n-type drain region 146, and a channel region 148. Each channel region 148 is positioned vertically between two gate regions 150 and positioned laterally between an n-type source region 144 and an n-type drain region 146.

Returning to FIGS. 1A-1C, these figures illustrate cross-sectional views of the structure 200 after etching of the dielectric region 182 and formation of the third source or drain contact region 186 to form CFET devices 100 and 102 with n-type GAAFETs 104 stacked vertically over p-type GAAFETs 106.

Any of the fabrication CFET device fabrication methods described herein, including method 800, may be performed using any suitable microelectronic fabrication techniques. For example, film deposition-such as depositing layers, filling (backfilling) portions of layers (e.g., filling removed portions of layers or removed layers), and filling via or contact openings—may be performed using any suitable deposition techniques, including, for example, chemical vapor deposition (CVD), metalorganic chemical vapor deposition (MOCVD), molecular beam epitaxy (MBE), atomic layer deposition (ALD), sputtering and/or physical vapor deposition (PVD). Moreover, layer patterning-such as dielectric, ferromagnet, magnetoelectric layer patterning—may be performed using any suitable techniques, such as photolithography-based patterning and etching (e.g., dry etching or wet etching).

Although non-crystalline silicon is used as the HPTFT material for the layers 142a-142b that form the n-type GAAFET source, drain, and channel regions, in other embodiments, other HPTFT materials can be used. In various embodiments, the HPTFT material can be a material that has a charge carrier mobility of greater than 5 cm²/(V·s), higher than 20 cm²/(V·s), higher than 50 cm²/(V·s), or higher than 100 cm²/(V·s). In various embodiments, the HPTFT material can be a material that has a charge carrier mobility between 5 cm²/(V·s) and 700 cm²/(V·s), including all values and ranges therein (including the range from 100 cm²/(V·s) to 700 cm²/(V·s)).

In various embodiments, the HPTFT material is a material that has a bandgap voltage greater than the bandgap voltage of silicon (e.g., 1.14 eV at 300K). In some examples, the HPTFT material is a material that has a bandgap voltage that is materially higher than the bandgap voltage of silicon (e.g., higher than 1.2 eV at 300K). In particular embodiments, the HPTFT material is a material that has a bandgap voltage greater than the bandgap voltage of silicon but lower than 6.5 eV at 300K, including all values and ranges therein. In various embodiments, the HPTFT material is a material that has a bandgap voltage that is greater than the bandgap voltage of a substrate upon which a transistor comprising the HPTFT material is formed.

In various embodiments, the HPTFT material comprises an oxide (e.g., a metal oxide), such as indium gallium zinc oxide (IGZO), indium tin oxide (ITO), indium zinc oxide (IZO), zinc oxide, indium oxide, gallium oxide, copper oxide, tin oxide, or another suitable oxide. In some oxides, a material with insulating properties may be introduced into the oxide to increase the bandgap voltage. For example, doping indium oxide with hafnium oxide (which exhibits insulating properties) will result in a composite HPTFT material with a wider bandgap than the indium oxide. Similarly, indium oxide or zinc oxide may be doped with gallium oxide (which exhibits insulating properties) to produce a composite HPTFT material with a wider bandgap voltage.

In some embodiments, the HPTFT material comprises a nitride (e.g., a metal nitride), such as zinc nitride, indium nitride, gallium nitride, copper nitride, aluminum nitride, or other suitable nitride. In some nitrides, a material with insulating properties may be introduced into the nitride to increase the bandgap voltage. For example, aluminum nitride (which exhibits insulating properties) may be added to indium nitride, zinc nitride, or gallium nitride to produce a composite HPTFT material with an increased bandgap voltage.

In some embodiments, the HPTFT material comprises a chalcogenide, such as a selenide or sulfide of molybdenum, tungsten, indium, gallium, zinc, copper, hafnium, aluminum, or germanium.

In some embodiments, the HPTFT material comprises any other suitable material, such as black phosphorous, graphene, carbon nanotubes, poly germanium, poly (3,5) (gallium arsenide, etc.). While some of these materials have a narrower bandgap voltage than silicon in certain compositions, the concentration of certain elements (e.g., gallium) may be increased to improve the bandgap voltage of the resulting HPTFT material.

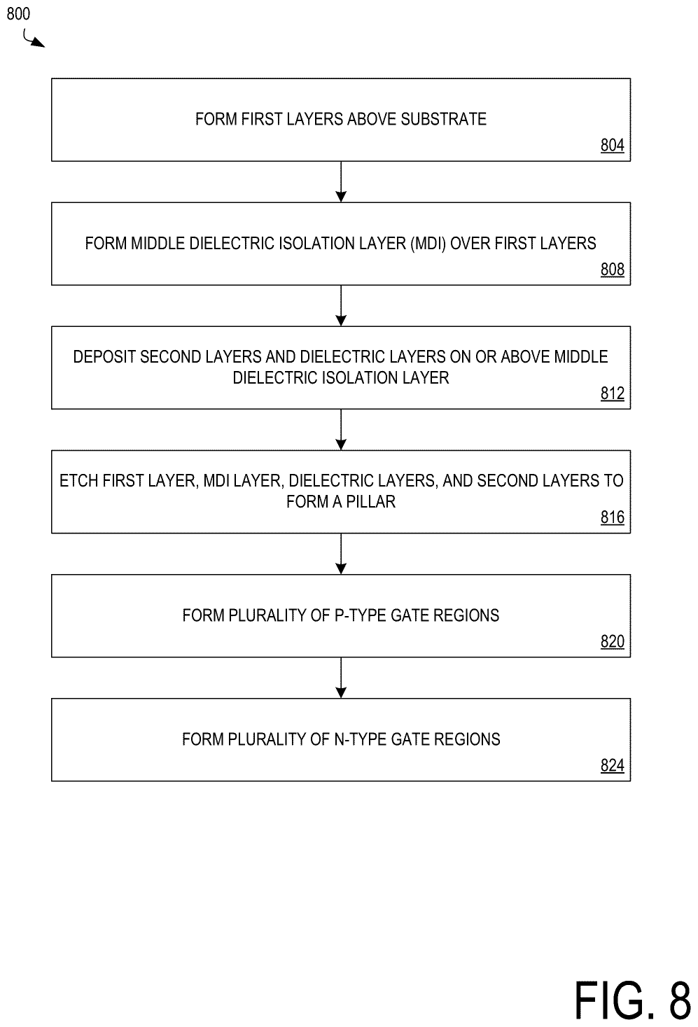

FIG. 8 is an example method of forming a CFET device with HPTFT materials. The method 800 can be performed by, for example an integrated circuit component manufacturer. At 804, a plurality of first layers is formed above a substrate, wherein the first layers are stacked vertically relative to a surface of the substate, individual of the first layers comprising silicon, individual of the first layers comprising a first region, a second region, and a third region, the first region positioned laterally between the second and third regions, the second and third regions comprising a p-type dopant. At 808, a middle dielectric layer is formed over the plurality of first layers. At 812, a plurality of second layers and a plurality of spacer regions are deposited on or above the middle dielectric layer, a bottommost spacer region deposited on the middle dielectric layer, individual of the second layers deposited on one of the spacer regions, individual of the second layers comprising non-crystalline silicon, individual of the second layers comprising a first region, a second region, and a third region, the first region positioned laterally between the second and third regions, the second and third regions comprising an n-type dopant. At 816, the first layers, the middle dielectric layer, the spacer regions, and the second layers are etched to form a pillar. At 820, a plurality of first gate regions is formed, individual of the first regions of the first layers positioned vertically between two first gate regions. At 824, a plurality of second gate regions is formed, individual of the first regions of the second layers positioned vertically between two second gate regions.

In other embodiments, the method 800 may have additional elements. For example, the method 800 can further comprise forming a first contact region positioned adjacent to an end of individual of the first portions of the first layers; and forming a second contact region positioned adjacent to an end of individual of the second portions of the first layers. In another example, the method 800 can further comprise forming a second contact region positioned adjacent to an end of individual of the first portions of the second layers; and forming a second contact region positioned adjacent to an end of individual of the second portions of the second layers. In yet another example, the method 800 can further comprise forming a gate contact region positioned adjacent to an uppermost first gate region.

The CFET devices described herein can be used in any processor unit or integrated circuit component described or referenced herein. An integrated circuit component comprising CFET devices can be attached to a printed circuit board (motherboard, mainboard). In some embodiments, one or more additional integrated circuit components or other components (e.g., battery, memory, antenna) can be attached to the printed circuit board. In some embodiments, the printed circuit board and the integrated circuit component can be located in a computing device that comprises a housing that encloses the printed circuit board and the integrated circuit component.

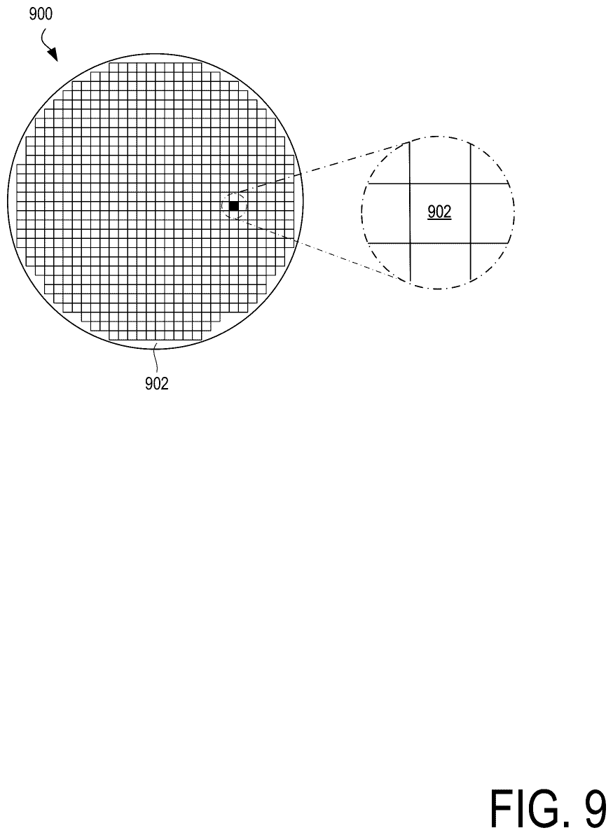

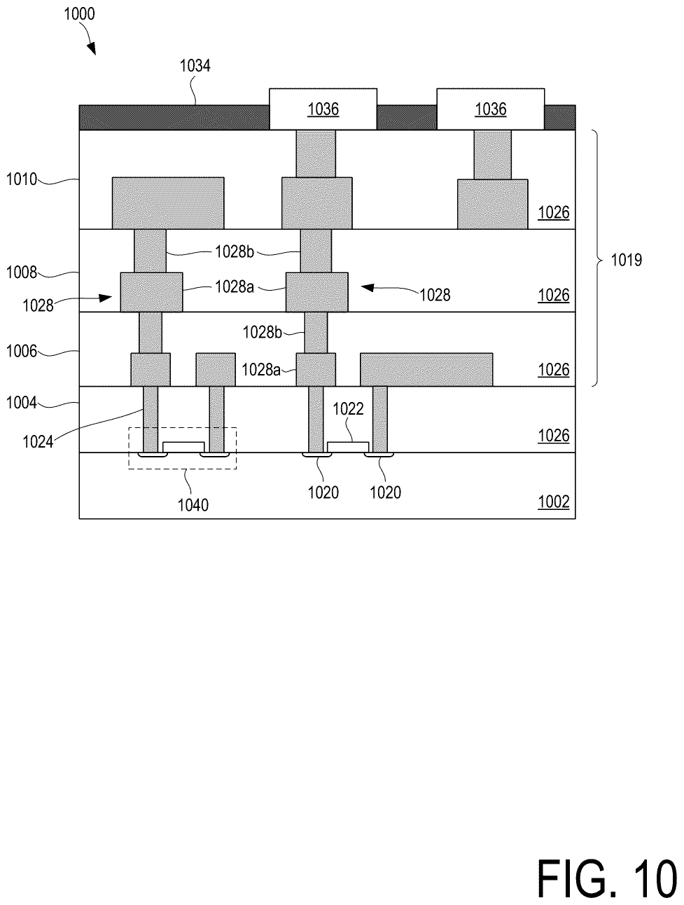

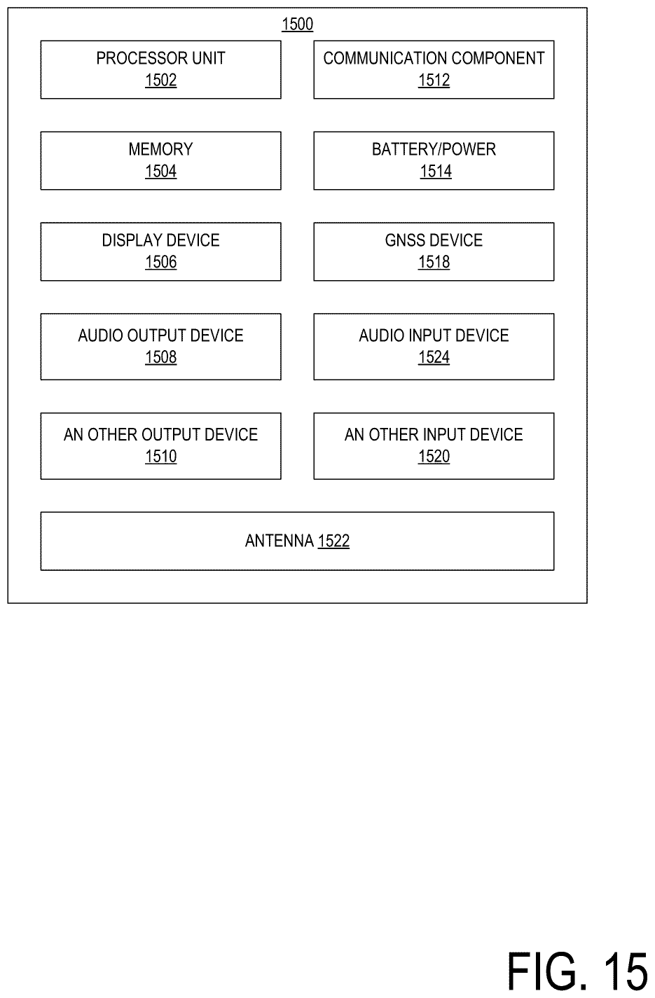

FIG. 9 is a top view of a wafer 900 and dies 902 that may be included in any of the microelectronic assemblies disclosed herein. The wafer 900 may be composed of semiconductor material and may include one or more dies 902 having integrated circuit structures formed on a surface of the wafer 900. The individual dies 902 may be a repeating unit of an integrated circuit product that includes any suitable integrated circuit. After the fabrication of the semiconductor product is complete, the wafer 900 may undergo a singulation process in which the dies 902 are separated from one another to provide discrete “chips” of the integrated circuit product. The die 902 may include one or more transistors (e.g., some of the CFET devices disclosed herein, some of transistors 1040 of FIG. 10, discussed below), supporting circuitry to route electrical signals to the transistors, passive components (e.g., signal traces, resistors, capacitors, or inductors), and/or any other integrated circuit components. In some embodiments, the wafer 900 or the die 902 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 902. For example, a memory array formed by multiple memory devices may be formed on a same die 902 as a processor unit (e.g., the processor unit 1502 of FIG. 15) or other logic that is configured to store information in the memory devices or execute instructions stored in the memory array. Various ones of the microelectronic assemblies disclosed herein may be manufactured using a die-to-wafer assembly technique in which some dies 902 are attached to a wafer 900 that include other dies attached the wafer 900, and the wafer 900 is subsequently singulated.

FIG. 10 is a cross-sectional side view of an integrated circuit device 1000 that may be included in any of the microelectronic assemblies disclosed herein. One or more of the integrated circuit devices 1000 may be included in one or more dies 902 (FIG. 9). The integrated circuit device 1000 may be formed on a die substrate 1002 (e.g., the wafer 900 of FIG. 9) and may be included in a die (e.g., the die 902 of FIG. 9). The die substrate 1002 may be a semiconductor substrate composed of semiconductor material systems including, for example, n-type or p-type materials systems (or a combination of both). The die substrate 1002 may include, for example, a crystalline substrate formed using a bulk silicon or a silicon-on-insulator (SOI) substructure. In some embodiments, the die substrate 1002 may be formed using alternative materials, which may or may not be combined with silicon, that include, but are not limited to, germanium, carbon, indium antimonide, lead telluride, indium arsenide, indium phosphide, gallium arsenide, gallium antimonide or diamond. Further materials classified as group II-VI, III-V, or IV may also be used to form the die substrate 1002. Although a few examples of materials from which the die substrate 1002 may be formed are described here, any material that may serve as a foundation for an integrated circuit device 1000 may be used. The die substrate 1002 may be part of a singulated die (e.g., the dies 902 of FIG. 9) or a wafer (e.g., the wafer 900 of FIG. 9).

The integrated circuit device 1000 may include one or more device layers 1004 disposed on the die substrate 1002. The device layer 1004 may include features of one or more transistors 1040 (e.g., metal oxide semiconductor field-effect transistors (MOSFETs)) formed on the die substrate 1002. The transistors 1040 may include, for example, one or more source and/or drain (S/D) regions 1020, a gate 1022 to control current flow between the S/D regions 1020, and one or more S/D contacts 1024 to route electrical signals to/from the S/D regions 1020. The transistors 1040 may include additional features not depicted for the sake of clarity, such as device isolation regions, gate contacts, and the like. The transistors 1040 are not limited to the type and configuration depicted in FIG. 10 and may include a wide variety of other types and configurations such as, for example, planar transistors, non-planar transistors, or a combination of both. Non-planar transistors may include FinFET transistors (such as double-gate transistors or tri-gate transistors) and wrap-around or gate-all-around transistors (such as nanoribbon, nanosheet, or nanowire transistors). Devices comprises non-planar transistors may include forksheet transistor and complementary FET (CFET) devices.

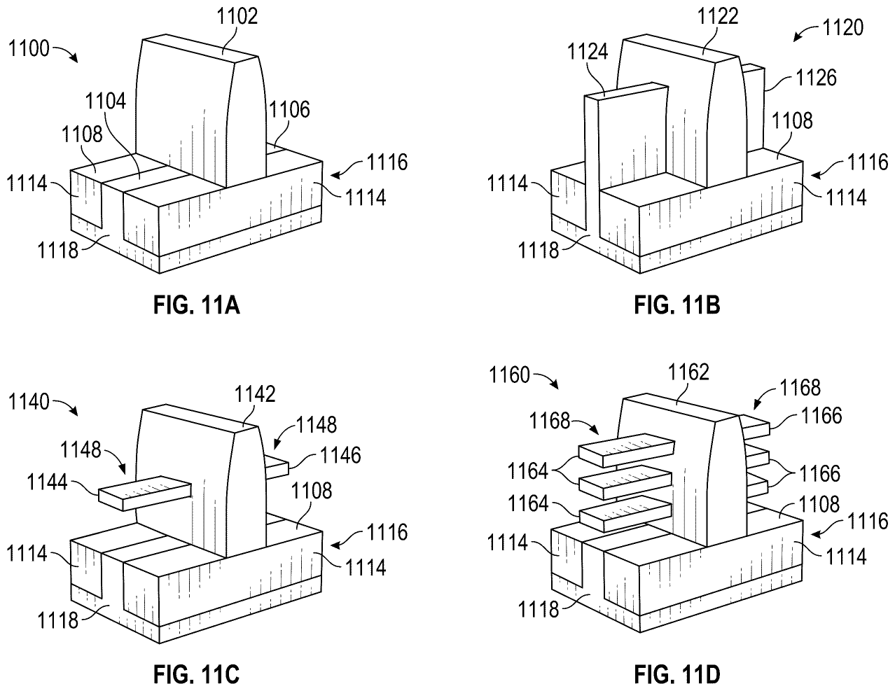

FIGS. 11A-11D are simplified perspective views of example planar, FinFET, gate-all-around, and stacked gate-all-around transistors. The transistors illustrated in FIGS. 11A-11D are formed on a substrate 1116 having a surface 1108. Isolation regions 1114 separate the source and drain regions of the transistors from other transistors and from a bulk region 1118 of the substrate 1116.

FIG. 11A is a perspective view of an example planar transistor 1100 comprising a gate 1102 that controls current flow between a source region 1104 and a drain region 1106. The transistor 1100 is planar in that the source region 1104 and the drain region 1106 are planar with respect to the substrate surface 1108.

FIG. 11B is a perspective view of an example FinFET transistor 1120 comprising a gate 1122 that controls current flow between a source region 1124 and a drain region 1126. The transistor 1120 is non-planar in that the source region 1124 and the drain region 1126 comprise “fins” that extend upwards from the substrate surface 1128. As the gate 1122 encompasses three sides of the semiconductor fin that extends from the source region 1124 to the drain region 1126, the transistor 1120 can be considered a tri-gate transistor. FIG. 11B illustrates one S/D fin extending through the gate 1122, but multiple S/D fins can extend through the gate of a FinFET transistor.

FIG. 11C is a perspective view of a gate-all-around (GAA) transistor (GAAFET) 1140 comprising a gate 1142 that controls current flow between a source region 1144 and a drain region 1146 of a strip 1148 comprising a semiconductor (semiconductor strip). The transistor 1140 is non-planar in that the strip 1148 is elevated from the substrate surface 1128.

FIG. 11D is a perspective view of a GAA transistor 1160 comprising a gate 1162 that controls current flow between source regions 1164 and drain regions 1166 of multiple elevated semiconductor strips 1168. The transistor 1160 is a stacked GAA transistor as the gate controls the flow of current between multiple elevated S/D regions stacked on top of each other. The transistors 1140 and 1160 can be referred to as gate-all-around transistors as the gates encompass all sides of the portions of the semiconductor strips that extend from the source regions to the drain regions. The transistors 1140 and 1160 can alternatively be referred to as nanowire, nanosheet, or nanoribbon transistors and the semiconductor strips that pass through the gate region can be referred to as nanowires, nanowires, or nanoribbons.

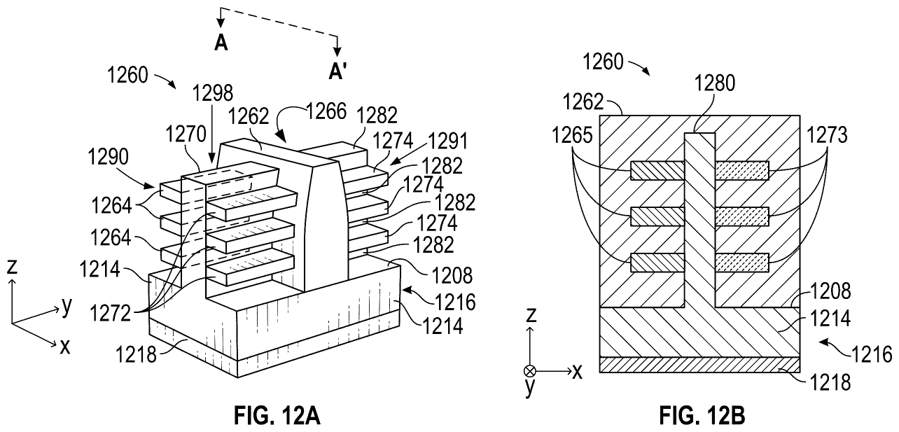

FIGS. 12A and 12B are perspective and cross-sectional views of an example forksheet transistor device. Generally, a forksheet transistor device comprises an n-type stacked GAAFET located next to a p-type stacked GAAFET with a dielectric region separating the nanoribbons (nanosheets, nanowires) forming the source, drain, and channel regions of the two GAAFETs. The forksheet transistor device 1260 is formed on a substrate 1216 having a surface 1208. The n-type and p-type GAAFETs comprise three vertically stacked nanoribbons 1290 and 1291, respectively. Each nanoribbon 1290 of the n-type GAAFET is coplanar with a nanoribbon 1291 of the p-type GAAFET. The substrate 1216 comprises an isolation region 1214 located on top of a bulk region 1218. A dielectric region 1298 separates the nanoribbons 1290 of the n-type GAAFET from the nanoribbons 1291 of the p-type GAAFET. A first portion 1270 of the dielectric region 1298 is positioned between n-type source regions 1264 and p-type source regions 1272, a second portion 1282 of the dielectric region 1298 is located between n-type drain regions 1266 (not viewable in FIG. 12A) and p-type drain regions 1274, and a third portion 1280 of the dielectric region 1298 is located between channel regions 1265 of nanoribbons 1290 and channel regions 1273 of nanoribbons 1291. In some embodiments, the dielectric region 1298 can be an extension of the substrate isolation region 1214. The gate 1262 controls current flow between the n-type source 1264 and drain 1266 regions, and the p-type source 1272 and drain 1274 regions.

FIG. 12B is a cross-sectional view of the gate region of the forksheet transistor device 1260 taken along the line A-A′ of FIG. 12A. Channel regions 1265 connect n-type source regions 1264 to n-type drain regions 1266, channel regions 1273 connect p-type source regions 1272 to p-type drain regions 1274, and the third portion 1280 of the dielectric region 1298 separates the channel regions 1265 from the channel regions 1273 and connects the first portion 1270 of the dielectric region 1298 to the second portion 1282 of the dielectric region 1298. Thus, the forksheet transistor device 1260 comprise an n-type transistor comprising n-type source regions 1264, channel region 1265, n-type drain regions 1266, and gate 1262; and a p-type transistor comprising p-type source regions 1272, channel regions 1273, p-type drain regions 1274, and gate 1262. The gate 1262 is shared by the n-type and p-type GAAFETs. The forksheet transistor architecture can provide for reduced spacing between n-type and p-type S/D regions in adjacent GAAFETs relative to that in adjacent independent GAAFETs of the type illustrated in FIG. 11D. The forksheet transistor architecture can thus allow for increased transistor packing density relative to the packing of independent GAAFETs or increased active transistor width at the same transistor packing density as independent GAAFETs.

FIGS. 13A-13B are simplified perspective and cross-sectional views, respectively, of an example complementary field-effect-transistor (CFET) device. FIG. 13B is a cross-sectional view of the CFET device 1300 taken through the gate region and taken along the line B-B′ of FIG. 13A. The CFET device 1300 comprises vertically stacked GAAFETs 1342 and 1344. In FIGS. 13A and 13B, transistor 1342 is an n-type transistor, and transistor 1344 is a p-type transistor, but in other embodiments, a CFET device can comprise a p-type transistor located above an n-type transistor. The transistors 1342 and 1344 are formed on a substrate 1316 having a surface 1308. The substrate 1316 comprises an isolation region 1314 located on top of a bulk region 1318.

The n-type and p-type transistors 1342 and 1344 comprise a gate 1382 shared by both transistors that controls current flow between the source and drain regions of nanoribbons 1310 and 1320, respectively. The transistors 1342 and 1344 comprise three nanoribbons but the transistors of a CFET device can have any number of nanoribbons and different transistors of a CFET device can have a different number of nanoribbons. The n-type transistor 1342 comprises n-type source regions 1364 connected to n-type drain regions 1366 by channel regions 1363 and the p-type transistor 1344 comprises p-type source regions 1372 connected to p-type drain regions 1374 by channel regions 1373. The transistor stacking employed by the CFET device architecture can provide for improved transistor density in the x- and y-dimensions or increased transistor width at the same transistor density relative to other gate-all-around transistor architectures, such as those illustrated in FIGS. 11D, 12A, and 12B. In some embodiments, the CFET device 1300 can be formed monolithically, with the upper and lower transistors formed on the same substrate, or sequentially, with the lower transistor (e.g., 1344) formed on a first substrate and the upper transistor (e.g., 1342) formed on a second substrate, the upper transistor integrated with the lower transistor through transfer of the upper transistor from the second substrate to the first substrate.

Returning to FIG. 10, a transistor 1040 may include a gate 1022 formed of at least two layers, a gate dielectric and a gate electrode. The gate dielectric may include one layer or a stack of layers. The one or more layers may include silicon oxide, silicon dioxide, silicon carbide, and/or a high-k dielectric material. A high-k dielectric material is a material having a dielectric constant greater than that of silicon dioxide).

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be conducted on the gate dielectric to improve its quality when a high-k material is used.

The gate electrode may be formed on the gate dielectric and may include at least one p-type work function metal or n-type work function metal, depending on whether the transistor 1040 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1040 along the source-channel-drain direction, the gate electrode may consist of a U-shaped structure that includes a bottom portion substantially parallel to the surface of the die substrate 1002 and two sidewall portions that are substantially perpendicular to the top surface of the die substrate 1002. In other embodiments, at least one of the metal layers that form the gate electrode may simply be a planar layer that is substantially parallel to the top surface of the die substrate 1002 and does not include sidewall portions substantially perpendicular to the top surface of the die substrate 1002. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1020 may be formed within the die substrate 1002 adjacent to the gate 1022 of individual transistors 1040. The S/D regions 1020 may be formed using an implantation/diffusion process or an etching/deposition process, for example. In the former process, dopants such as boron, aluminum, antimony, phosphorous, or arsenic may be ion-implanted into the die substrate 1002 to form the S/D regions 1020. An annealing process that activates the dopants and causes them to diffuse farther into the die substrate 1002 may follow the ion-implantation process. In the latter process, the die substrate 1002 may first be etched to form recesses at the locations of the S/D regions 1020. An epitaxial deposition process may then be conducted to fill the recesses with material that is used to fabricate the S/D regions 1020. In some implementations, the S/D regions 1020 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1020 may be formed using one or more alternate semiconductor materials such as germanium or a group III-V material or alloy. In further embodiments, one or more layers of metal and/or metal alloys may be used to form the S/D regions 1020.

Electrical signals, such as power and/or input/output (I/O) signals, may be routed to and/or from the devices (e.g., transistors 1040) of the device layer 1004 through one or more interconnect layers disposed on the device layer 1004 (illustrated in FIG. 10 as interconnect layers 1006-1010). For example, electrically conductive features of the device layer 1004 (e.g., the gate 1022 and the S/D contacts 1024) may be electrically coupled with the interconnect structures 1028 of the interconnect layers 1006-1010. The one or more interconnect layers 1006-1010 may form a metallization stack (also referred to as an “ILD stack”) 1019 of the integrated circuit device 1000.

The interconnect structures 1028 may be arranged within the interconnect layers 1006-1010 to route electrical signals according to a wide variety of designs; in particular, the arrangement is not limited to the particular configuration of interconnect structures 1028 depicted in FIG. 10. Although a particular number of interconnect layers 1006-1010 is depicted in FIG. 10, embodiments of the present disclosure include integrated circuit devices having more or fewer interconnect layers than depicted.

In some embodiments, the interconnect structures 1028 may include lines 1028a and/or vias 1028b filled with an electrically conductive material such as a metal. The lines 1028a may be arranged to route electrical signals in a direction of a plane that is substantially parallel with a surface of the die substrate 1002 upon which the device layer 1004 is formed. For example, the lines 1028a may route electrical signals in a direction in and out of the page and/or in a direction across the page from the perspective of FIG. 10. The vias 1028b may be arranged to route electrical signals in a direction of a plane that is substantially perpendicular to the surface of the die substrate 1002 upon which the device layer 1004 is formed. In some embodiments, the vias 1028b may electrically couple lines 1028a of different interconnect layers 1006-1010 together.

The interconnect layers 1006-1010 may include a dielectric material 1026 disposed between the interconnect structures 1028, as shown in FIG. 10. In some embodiments, dielectric material 1026 disposed between the interconnect structures 1028 in different ones of the interconnect layers 1006-1010 may have different compositions; in other embodiments, the composition of the dielectric material 1026 between different interconnect layers 1006-1010 may be the same. The device layer 1004 may include a dielectric material 1026 disposed between the transistors 1040 and a bottom layer of the metallization stack as well. The dielectric material 1026 included in the device layer 1004 may have a different composition than the dielectric material 1026 included in the interconnect layers 1006-1010; in other embodiments, the composition of the dielectric material 1026 in the device layer 1004 may be the same as a dielectric material 1026 included in any one of the interconnect layers 1006-1010.

A first interconnect layer 1006 (referred to as Metal 1 or “M1”) may be formed directly on the device layer 1004. In some embodiments, the first interconnect layer 1006 may include lines 1028a and/or vias 1028b, as shown. The lines 1028a of the first interconnect layer 1006 may be coupled with contacts (e.g., the S/D contacts 1024) of the device layer 1004. The vias 1028b of the first interconnect layer 1006 may be coupled with the lines 1028a of a second interconnect layer 1008.

The second interconnect layer 1008 (referred to as Metal 2 or “M2”) may be formed directly on the first interconnect layer 1006. In some embodiments, the second interconnect layer 1008 may include via 1028b to couple the lines 1028 of the second interconnect layer 1008 with the lines 1028a of a third interconnect layer 1010. Although the lines 1028a and the vias 1028b are structurally delineated with a line within individual interconnect layers for the sake of clarity, the lines 1028a and the vias 1028b may be structurally and/or materially contiguous (e.g., simultaneously filled during a dual-damascene process) in some embodiments.

The third interconnect layer 1010 (referred to as Metal 3 or “M3”) (and additional interconnect layers, as desired) may be formed in succession on the second interconnect layer 1008 according to similar techniques and configurations described in connection with the second interconnect layer 1008 or the first interconnect layer 1006. In some embodiments, the interconnect layers that are “higher up” in the metallization stack 1019 in the integrated circuit device 1000 (i.e., farther away from the device layer 1004) may be thicker that the interconnect layers that are lower in the metallization stack 1019, with lines 1028a and vias 1028b in the higher interconnect layers being thicker than those in the lower interconnect layers.

The integrated circuit device 1000 may include a solder resist material 1034 (e.g., polyimide or similar material) and one or more conductive contacts 1036 formed on the interconnect layers 1006-1010. In FIG. 10, the conductive contacts 1036 are illustrated as taking the form of bond pads. The conductive contacts 1036 may be electrically coupled with the interconnect structures 1028 and configured to route the electrical signals of the transistor(s) 1040 to external devices. For example, solder bonds may be formed on the one or more conductive contacts 1036 to mechanically and/or electrically couple an integrated circuit die including the integrated circuit device 1000 with another component (e.g., a printed circuit board). The integrated circuit device 1000 may include additional or alternate structures to route the electrical signals from the interconnect layers 1006-1010; for example, the conductive contacts 1036 may include other analogous features (e.g., posts) that route the electrical signals to external components.

In some embodiments in which the integrated circuit device 1000 is a double-sided die, the integrated circuit device 1000 may include another metallization stack (not shown) on the opposite side of the device layer(s) 1004. This metallization stack may include multiple interconnect layers as discussed above with reference to the interconnect layers 1006-1010, to provide conductive pathways (e.g., including conductive lines and vias) between the device layer(s) 1004 and additional conductive contacts (not shown) on the opposite side of the integrated circuit device 1000 from the conductive contacts 1036.

In other embodiments in which the integrated circuit device 1000 is a double-sided die, the integrated circuit device 1000 may include one or more through silicon vias (TSVs) through the die substrate 1002; these TSVs may make contact with the device layer(s) 1004, and may provide conductive pathways between the device layer(s) 1004 and additional conductive contacts (not shown) on the opposite side of the integrated circuit device 1000 from the conductive contacts 1036. In some embodiments, TSVs extending through the substrate can be used for routing power and ground signals from conductive contacts on the opposite side of the integrated circuit device 1000 from the conductive contacts 1036 to the transistors 1040 and any other components integrated into the die 1000, and the metallization stack 1019 can be used to route I/O signals from the conductive contacts 1036 to transistors 1040 and any other components integrated into the die 1000.

Multiple integrated circuit devices 1000 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

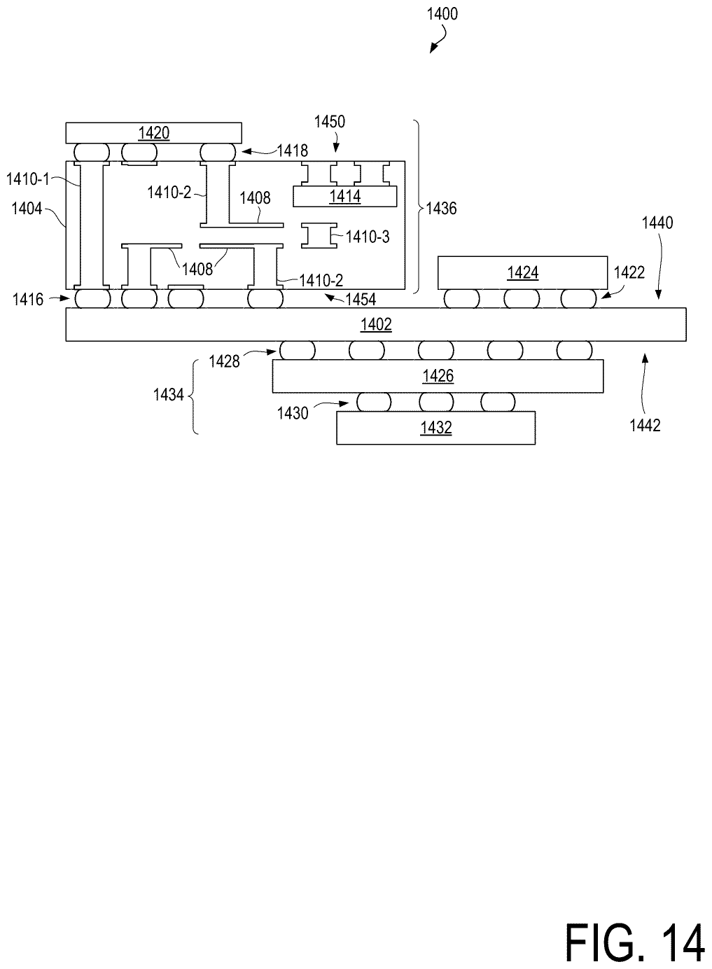

FIG. 14 is a cross-sectional side view of an integrated circuit device assembly 1400 that may include any of the microelectronic assemblies disclosed herein. The integrated circuit device assembly 1400 includes a number of components disposed on a circuit board 1402 (which may be a motherboard, system board, mainboard, etc.). The integrated circuit device assembly 1400 includes components disposed on a first face 1440 of the circuit board 1402 and an opposing second face 1442 of the circuit board 1402; generally, components may be disposed on one or both faces 1440 and 1442.

In some embodiments, the circuit board 1402 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1402. In other embodiments, the circuit board 1402 may be a non-PCB substrate. The integrated circuit device assembly 1400 illustrated in FIG. 14 includes a package-on-interposer structure 1436 coupled to the first face 1440 of the circuit board 1402 by coupling components 1416. The coupling components 1416 may electrically and mechanically couple the package-on-interposer structure 1436 to the circuit board 1402, and may include solder balls (as shown in FIG. 14), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1416 may serve as the coupling components illustrated or described for any of the substrate assembly or substrate assembly components described herein, as appropriate.

The package-on-interposer structure 1436 may include an integrated circuit component 1420 coupled to an interposer 1404 by coupling components 1418. The coupling components 1418 may take any suitable form for the application, such as the forms discussed above with reference to the coupling components 1416. Although a single integrated circuit component 1420 is shown in FIG. 14, multiple integrated circuit components may be coupled to the interposer 1404; indeed, additional interposers may be coupled to the interposer 1404. The interposer 1404 may provide an intervening substrate used to bridge the circuit board 1402 and the integrated circuit component 1420.

The integrated circuit component 1420 may be a packaged or unpacked integrated circuit product that includes one or more integrated circuit dies (e.g., the die 902 of FIG. 9, the integrated circuit device 1000 of FIG. 10) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1420, a single monolithic integrated circuit die comprises solder bumps attached to contacts on the die. The solder bumps allow the die to be directly attached to the interposer 1404. The integrated circuit component 1420 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1420 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1420 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1420 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1404 may spread connections to a wider pitch or reroute a connection to a different connection. For example, the interposer 1404 may couple the integrated circuit component 1420 to a set of ball grid array (BGA) conductive contacts of the coupling components 1416 for coupling to the circuit board 1402. In the embodiment illustrated in FIG. 14, the integrated circuit component 1420 and the circuit board 1402 are attached to opposing sides of the interposer 1404; in other embodiments, the integrated circuit component 1420 and the circuit board 1402 may be attached to a same side of the interposer 1404. In some embodiments, three or more components may be interconnected by way of the interposer 1404.

In some embodiments, the interposer 1404 may be formed as a PCB, including multiple metal layers separated from one another by layers of dielectric material and interconnected by electrically conductive vias. In some embodiments, the interposer 1404 may be formed of an epoxy resin, a fiberglass-reinforced epoxy resin, an epoxy resin with inorganic fillers, a ceramic material, or a polymer material such as polyimide. In some embodiments, the interposer 1404 may be formed of alternate rigid or flexible materials that may include the same materials described above for use in a semiconductor substrate, such as silicon, germanium, and other group III-V and group IV materials. The interposer 1404 may include metal interconnects 1408 and vias 1410, including but not limited to through hole vias 1410-1 (that extend from a first face 1450 of the interposer 1404 to a second face 1454 of the interposer 1404), blind vias 1410-2 (that extend from the first or second faces 1450 or 1454 of the interposer 1404 to an internal metal layer), and buried vias 1410-3 (that connect internal metal layers).

In some embodiments, the interposer 1404 can comprise a silicon interposer. Through silicon vias (TSV) extending through the silicon interposer can connect connections on a first face of a silicon interposer to an opposing second face of the silicon interposer. In some embodiments, an interposer 1404 comprising a silicon interposer can further comprise one or more routing layers to route connections on a first face of the interposer 1404 to an opposing second face of the interposer 1404.

The interposer 1404 may further include embedded devices 1414, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1404. The package-on-interposer structure 1436 may take the form of any of the package-on-interposer structures known in the art.

The integrated circuit device assembly 1400 may include an integrated circuit component 1424 coupled to the first face 1440 of the circuit board 1402 by coupling components 1422. The coupling components 1422 may take the form of any of the embodiments discussed above with reference to the coupling components 1416, and the integrated circuit component 1424 may take the form of any of the embodiments discussed above with reference to the integrated circuit component 1420.

The integrated circuit device assembly 1400 illustrated in FIG. 14 includes a package-on-package structure 1434 coupled to the second face 1442 of the circuit board 1402 by coupling components 1428. The package-on-package structure 1434 may include an integrated circuit component 1426 and an integrated circuit component 1432 coupled together by coupling components 1430 such that the integrated circuit component 1426 is disposed between the circuit board 1402 and the integrated circuit component 1432. The coupling components 1428 and 1430 may take the form of any of the embodiments of the coupling components 1416 discussed above, and the integrated circuit components 1426 and 1432 may take the form of any of the embodiments of the integrated circuit component 1420 discussed above. The package-on-package structure 1434 may be configured in accordance with any of the package-on-package structures known in the art.

FIG. 15 is a block diagram of an example electrical device 1500 that may include one or more of the microelectronic assemblies disclosed herein. For example, any suitable ones of the components of the electrical device 1500 may include one or more of the integrated circuit device assemblies 1400, integrated circuit components 1420, integrated circuit devices 1000, or integrated circuit dies 902 disclosed herein, and may be arranged in any of the microelectronic assemblies disclosed herein. A number of components are illustrated in FIG. 15 as included in the electrical device 1500, but any one or more of these components may be omitted or duplicated, as suitable for the application. In some embodiments, some or all of the components included in the electrical device 1500 may be attached to one or more motherboards mainboards, or system boards. In some embodiments, one or more of these components are fabricated onto a single system-on-a-chip (SoC) die.

Additionally, in various embodiments, the electrical device 1500 may not include one or more of the components illustrated in FIG. 15, but the electrical device 1500 may include interface circuitry for coupling to the one or more components. For example, the electrical device 1500 may not include a display device 1506, but may include display device interface circuitry (e.g., a connector and driver circuitry) to which a display device 1506 may be coupled. In another set of examples, the electrical device 1500 may not include an audio input device 1524 or an audio output device 1508, but may include audio input or output device interface circuitry (e.g., connectors and supporting circuitry) to which an audio input device 1524 or audio output device 1508 may be coupled.

The electrical device 1500 may include one or more processor units 1502 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1502 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1500 may include a memory 1504, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1504 may include memory that is located on the same integrated circuit die as the processor unit 1502. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 1500 can comprise one or more processor units 1502 that are heterogeneous or asymmetric to another processor unit 1502 in the electrical device 1500. There can be a variety of differences between the processing units 1502 in a system in terms of a spectrum of metrics of merit including architectural, microarchitectural, thermal, power consumption characteristics, and the like. These differences can effectively manifest themselves as asymmetry and heterogeneity among the processor units 1502 in the electrical device 1500.

In some embodiments, the electrical device 1500 may include a communication component 1512 (e.g., one or more communication components). For example, the communication component 1512 can manage wireless communications for the transfer of data to and from the electrical device 1500. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1512 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1512 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1512 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1512 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1512 may operate in accordance with other wireless protocols in other embodiments. The electrical device 1500 may include an antenna 1522 to facilitate wireless communications and/or to receive other wireless communications (such as AM or FM radio transmissions).

In some embodiments, the communication component 1512 may manage wired communications, such as electrical, optical, or any other suitable communication protocols (e.g., IEEE 802.3 Ethernet standards). As noted above, the communication component 1512 may include multiple communication components. For instance, a first communication component 1512 may be dedicated to shorter-range wireless communications such as Wi-Fi or Bluetooth, and a second communication component 1512 may be dedicated to longer-range wireless communications such as global positioning system (GPS), EDGE, GPRS, CDMA, WiMAX, LTE, EV-DO, or others. In some embodiments, a first communication component 1512 may be dedicated to wireless communications, and a second communication component 1512 may be dedicated to wired communications.

The electrical device 1500 may include battery/power circuitry 1514. The battery/power circuitry 1514 may include one or more energy storage devices (e.g., batteries or capacitors) and/or circuitry for coupling components of the electrical device 1500 to an energy source separate from the electrical device 1500 (e.g., AC line power).

The electrical device 1500 may include a display device 1506 (or corresponding interface circuitry, as discussed above). The display device 1506 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1500 may include an audio output device 1508 (or corresponding interface circuitry, as discussed above). The audio output device 1508 may include any embedded or wired or wirelessly connected external device that generates an audible indicator, such speakers, headsets, or earbuds.

The electrical device 1500 may include an audio input device 1524 (or corresponding interface circuitry, as discussed above). The audio input device 1524 may include any embedded or wired or wirelessly connected device that generates a signal representative of a sound, such as microphones, microphone arrays, or digital instruments (e.g., instruments having a musical instrument digital interface (MIDI) output). The electrical device 1500 may include a Global Navigation Satellite System (GNSS) device 1518 (or corresponding interface circuitry, as discussed above), such as a Global Positioning System (GPS) device. The GNSS device 1518 may be in communication with a satellite-based system and may determine a geolocation of the electrical device 1500 based on information received from one or more GNSS satellites, as known in the art.

The electrical device 1500 may include another output device 1510 (or corresponding interface circuitry, as discussed above). Examples of the other output device 1510 may include an audio codec, a video codec, a printer, a wired or wireless transmitter for providing information to other devices, or an additional storage device.

The electrical device 1500 may include another input device 1520 (or corresponding interface circuitry, as discussed above). Examples of the other input device 1520 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1500 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1500 may be any other electronic device that processes data. In some embodiments, the electrical device 1500 may comprise multiple discrete physical components. Given the range of devices that the electrical device 1500 can be manifested as in various embodiments, in some embodiments, the electrical device 1500 can be referred to as a computing device or a computing system.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C. Furthermore, as used in this application and the claims, a list of items joined by the term “one of” can mean any one of the listed items. For example, the phrase “one of A, B, and C” can mean A, B, or C.

As used in this application and the claims, the phrase “individual of” or “respective of” following by a list of items recited or stated as having a trait, feature, etc. means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example 1 is an apparatus comprising a substrate comprising silicon; a plurality of first layers stacked vertically with respect to a surface of the substrate, wherein individual of the first layers comprise a first source or drain (S/D) region, a second S/D region, and a first channel region positioned between the first S/D region and the second S/D region, wherein individual of the first layers comprise non-crystalline silicon, and wherein the first S/D region and the second S/D region of the individual first layers comprise an n-type dopant; and a plurality of second layers stacked vertically with respect to the surface of the substrate, wherein individual of the second layers comprise a third S/D region, a fourth S/D region, and a second channel region, wherein individual of the second layers comprise silicon, and wherein the third S/D region and the fourth S/D region of the individual second layers comprise a p-type dopant; a middle dielectric layer positioned between the plurality of first layers and the plurality of second layers; a plurality of first gate regions stacked vertically with respect to the surface of the substrate, the first gate regions comprising a first gate dielectric layer and all but the topmost first gate regions further comprising a first gate electrode encircled by the first gate dielectric layer, wherein the first gate electrodes comprise a first metal, and wherein individual of the first channel regions are positioned adjacent to two first gate regions; and a plurality of second gate regions stacked vertically with respect to the surface of the substrate, wherein individual of the second gate regions comprise a second gate dielectric layer and a second gate electrode, the second gate dielectric layer encircling the second gate electrode, the second gate electrode comprising a first metal or a second metal, individual of the second channel regions positioned adjacent to two second gate regions.

Example 2 includes the subject matter of Example 1, and further including a plurality of first spacer regions stacked vertically with respect to the surface of the substrate, wherein a first portion of one of the first spacer regions is positioned between the middle dielectric layer and at least a portion of the first S/D region of the first layer positioned nearest to the middle dielectric layer, a second portion of the one of the first spacer regions is positioned between the middle dielectric layer and at least a portion of the second S/D region of the first layer positioned nearest to the middle dielectric layer, a first portion of individual of the other first spacer regions positioned adjacent to at least a portion of the first S/D region of two of the first layers, and a second portion of individual of the other first spacer regions positioned adjacent to at least a portion of the second S/D region of two of the first layers; and a plurality of second spacer regions stacked vertically with respect to the surface of the substrate, wherein a first portion of one of the second spacer regions is positioned between the middle dielectric layer and at least a portion of the third S/D region of the second layer positioned nearest to the middle dielectric layer, a second portion of the one of the second spacer regions is positioned between the middle dielectric layer and at least a portion of the fourth S/D region of the second layer positioned nearest to the middle dielectric layer, a first portion of individual of the other second spacer regions positioned adjacent to at least a portion of the third S/D region of two of the second layers, and a second portion of individual of the other second spacer regions positioned adjacent to at least a portion of the second S/D region of two of the second layers.

Example 3 includes the subject matter of Example 1 or 2, further comprising a contact region comprising the first metal, the second metal, or another metal, individual of the first S/D regions of the first layers comprising an end positioned adjacent to the contact region.

Example 4 includes the subject matter of Example 3, and wherein the contact region is a first contact region, the apparatus further comprising a second contact region comprising the first metal, the second metal, or another metal, individual of the third S/D regions of the second layers comprising an end positioned adjacent to the second contact region.

Example 5 includes the subject matter of Example 3, and wherein the contact region comprises tungsten, cobalt, titanium, gold, aluminum, molybdenum, chromium, or nickel.

Example 6 includes the subject matter of Example 1 or 2, further comprising a gate contact region comprising the first metal, the second metal, or another metal, the gate contact region positioned adjacent to the first gate region positioned furthest away from the middle dielectric layer.

Example 7 is an apparatus comprising a substrate comprising silicon; a plurality of first layers stacked vertically with respect to a surface of the substrate, individual of the first layers comprising non-crystalline silicon and an n-type dopant; a plurality of second layers stacked vertically with respect to the surface of the substrate, individual of the second layers comprising silicon and a p-type dopant; and a middle dielectric layer positioned between the plurality of first layers and the plurality of second layers.

Example 8 includes the subject matter of Example 7, and further including a plurality of first spacer regions stacked vertically with respect to the surface of the substrate, wherein a first spacer region is positioned between the middle dielectric layer and a first layer positioned nearest to the middle dielectric layer, the other first spacer regions positioned adjacent to two of the first layers; and a plurality of second spacer regions stacked vertically with respect to the surface of the substrate, wherein a second spacer regions is positioned between the middle dielectric layer and a second layer positioned nearest to the middle dielectric layer, the other second spacer regions positioned adjacent to two of the second layers.

Example 9 includes the subject matter of any one of Examples 1-8, wherein the non-crystalline silicon of the first layers comprises amorphous silicon.

Example 10 includes the subject matter of any one of Examples 1-8, wherein the non-crystalline silicon of the first layers comprises polycrystalline silicon.

Example 11 includes the subject matter of Example 2 or 8, wherein the first spacer regions comprise silicon and oxygen; silicon, oxygen, and one of carbon, fluorine, and hydrogen; or silicon and nitrogen.

Example 12 includes the subject matter of Example 2 or 8, wherein the second spacer regions comprise silicon and oxygen; silicon, oxygen, and one of carbon, fluorine, and hydrogen; or silicon and nitrogen.

Example 13 includes the subject matter of any one of Examples 1-12, wherein the n-type dopant is phosphorous, arsenic, or antimony.

Example 14 includes the subject matter of any one of Examples 1-13, wherein the p-type dopant is boron or gallium.

Example 15 includes the subject matter of any one of Examples 1-14, wherein the middle dielectric layer comprises silicon and oxygen; silicon, oxygen, and one of carbon, fluorine, or hydrogen; or silicon and nitrogen.

Example 16 includes the subject matter of any one of Examples 1-15, wherein the first metal comprises hafnium, zirconium, titanium, tantalum, aluminum.

Example 17 includes the subject matter of Example 16, the first metal further comprises carbon.

Example 18 includes the subject matter of any one of Examples 1-15, wherein the first metal comprises ruthenium, palladium, platinum, cobalt, or nickel.

Example 19 includes the subject matter of any one of Examples 1-18, wherein the second metal comprises hafnium, zirconium, titanium, tantalum, or aluminum.

Example 20 includes the subject matter of Example 19, the second metal further comprises carbon.

Example 21 includes the subject matter of any one of Examples 1-18, wherein the second metal comprises ruthenium, palladium, platinum, cobalt, or nickel.

Example 22 includes the subject matter of Example 1-15, wherein the first metal and/or the second metal comprises oxygen and a metal.

Example 23 includes the subject matter of Example 1-22, wherein the first gate dielectric layers comprises a first dielectric material having a dielectric constant greater than silicon dioxide and the second dielectric layers comprises the first dielectric material or a second dielectric material having a dielectric constant greater than silicon dioxide.

Example 24 includes the subject matter of Example 1-22, wherein the first gate dielectric layers comprise hafnium and oxygen; hafnium, oxygen, and silicon; lanthanum and oxygen; lanthanum, oxygen, and aluminum; zirconium and oxygen; zirconium, oxygen, and silicon; tantalum and oxygen; titanium and oxygen; barium, strontium, titanium, and oxygen; barium, titanium, and oxygen; strontium, titanium, and oxygen; yttrium and oxygen; aluminum and oxygen; lead, scandium, tantalum, and oxygen; or lead, zinc, and niobium.

Example 25 includes the subject matter of Example 1-12, wherein the second gate dielectric layers comprise hafnium and oxygen; hafnium, oxygen, and silicon; lanthanum and oxygen; lanthanum, oxygen, and aluminum; zirconium and oxygen; zirconium, oxygen, and silicon; tantalum and oxygen; titanium and oxygen; barium, strontium, titanium, and oxygen; barium, titanium, and oxygen; strontium, titanium, and oxygen; yttrium and oxygen; aluminum and oxygen; lead, scandium, tantalum, and oxygen; or lead, zinc, and niobium.

Example 26 includes the subject matter of any one of Examples 1-25, wherein the plurality of second layers is positioned between the middle dielectric layer and the substrate.

Example 27 includes the subject matter of any one of Examples 1-25, wherein the plurality of first layers is positioned between the middle dielectric layer and the substrate.

Example 28 includes the subject matter of any one of Examples 1-27, wherein the apparatus is a wafer.

Example 29 includes the subject matter of any one of Examples 1-27, wherein the apparatus is an integrated circuit component.

Example 30 includes the subject matter of any one of Examples 1-29, further comprising a printed circuit board, the integrated circuit component attached to the printed circuit board.

Example 31 includes the subject matter of Example 30, and wherein a memory is attached to the printed circuit board.

Example 32 includes the subject matter of Example 30, and further including a housing of a computing device enclosing the printed circuit board.

Example 33 includes a method comprising forming a plurality of first layers above a substrate, wherein the first layers are stacked vertically relative to a surface of the substate, individual of the first layers comprising silicon, individual of the first layers comprising a first region, a second region, and a third region, the first region positioned laterally between the second and third regions, the second and third regions comprising a p-type dopant; forming a middle dielectric layer over the plurality of first layers; depositing a plurality of second layers and a plurality of spacer regions on or above the middle dielectric layer, a bottommost spacer region deposited on the middle dielectric layer, individual of the second layers deposited on one of the spacer regions, individual of the second layers comprising non-crystalline silicon, individual of the second layers comprising a first region, a second region, and a third region, the first region positioned laterally between the second and third regions, the second and third regions comprising an n-type dopant; etching the first layers, the middle dielectric layer, the spacer regions, and the second layers to form a pillar; forming a plurality of first gate regions, individual of the first regions of the first layers positioned vertically between two first gate regions; and forming a plurality of second gate regions, individual of the first regions of the second layers positioned vertically between two second gate regions.

Example 34 includes the subject matter of Example 33, and further including forming a first contact region positioned adjacent to an end of individual of the first regions of the first layers; and forming a second contact region positioned adjacent to an end of individual of the second regions of the first layers.

Example 35 includes the subject matter of any of Examples 33 and 34, and further including forming a first contact region positioned adjacent to an end of individual of the first regions of the second layers; and forming a second contact region positioned adjacent to an end of individual of the second regions of the second layers.

Example 36 includes the subject matter of Example 34 or 35, wherein the first contact region and the second contact region comprise tungsten, cobalt, titanium, gold, aluminum, molybdenum, chromium, or nickel.

Example 37 includes the subject matter of any one of Example 33-36, further comprising forming a gate contact region positioned adjacent to the first gate region positioned furthest from the middle dielectric layer.

Example 38 includes the subject matter of any one of Examples 33-37, wherein the non-crystalline silicon of the second layers comprises amorphous silicon.

Example 39 includes the subject matter of any one of Examples 33-37, wherein the non-crystalline silicon of the second layers comprises polycrystalline silicon.

Example 40 includes the subject matter of any one of Examples 33-39, wherein the n-type dopant is phosphorous, arsenic, or antimony.

Example 41 includes the subject matter of any one of Examples 33-40, wherein the p-type dopant is boron or gallium.

Example 42 includes the subject matter of any one of Examples 33-41, wherein the middle dielectric layer comprises silicon and oxygen; silicon, oxygen, and one of carbon, fluorine, or hydrogen; or silicon and nitrogen.

Example 43 includes the subject matter of Example 33, and wherein individual of the first gate regions comprise a gate dielectric layer and a gate electrode.

Example 44 includes the subject matter of Example 33, and wherein individual of the second gate regions comprise a gate dielectric layer and a gate electrode.

Example 45 includes the subject matter of Example 43 or 44, wherein the gate electrode comprises hafnium, zirconium, titanium, tantalum, aluminum.

Example 46 includes the subject matter of Example 44, the gate electrode further comprises carbon.

Example 47 includes the subject matter of any Example 43 or 44, wherein the gate electrode comprises ruthenium, palladium, platinum, cobalt, or nickel.

Example 48 includes the subject matter of Example 43 or 44, wherein the gate dielectric layer comprises a dielectric material having a dielectric constant greater than silicon dioxide.

Example 49 includes the subject matter of Example 33, and wherein the gate dielectric layer comprises hafnium and oxygen; hafnium, oxygen, and silicon; lanthanum and oxygen; lanthanum, oxygen, and aluminum; zirconium and oxygen; zirconium, oxygen, and silicon; tantalum and oxygen; titanium and oxygen; barium, strontium, titanium, and oxygen; barium, titanium, and oxygen; strontium, titanium, and oxygen; yttrium and oxygen; aluminum and oxygen; lead, scandium, tantalum, and oxygen; or lead, zinc, and niobium.

1. An apparatus comprising:
a substrate comprising silicon;
a plurality of first layers stacked vertically with respect to a surface of the substrate, wherein individual of the first layers comprise a first source or drain (S/D) region, a second S/D region, and a first channel region positioned between the first S/D region and the second S/D region, wherein individual of the first layers comprise non-crystalline silicon, and wherein the first S/D region and the second S/D region of the individual first layers comprise an n-type dopant; and
a plurality of second layers stacked vertically with respect to the surface of the substrate, wherein individual of the second layers comprise a third S/D region, a fourth S/D region, and a second channel region, wherein individual of the second layers comprise silicon, and wherein the third S/D region and the fourth S/D region of the individual second layers comprise a p-type dopant;
a middle dielectric layer positioned between the plurality of first layers and the plurality of second layers;
a plurality of first gate regions stacked vertically with respect to the surface of the substrate, the first gate regions comprising a first gate dielectric layer and all but the topmost first gate regions further comprising a first gate electrode encircled by the first gate dielectric layer, wherein the first gate electrodes comprise a first metal, and wherein individual of the first channel regions are positioned adjacent to two first gate regions; and
a plurality of second gate regions stacked vertically with respect to the surface of the substrate, wherein individual of the second gate regions comprise a second gate dielectric layer and a second gate electrode, the second gate dielectric layer encircling the second gate electrode, the second gate electrode comprising a first metal or a second metal, individual of the second channel regions positioned adjacent to two second gate regions.

2. The apparatus of claim 1, further comprising:
a plurality of first spacer regions stacked vertically with respect to the surface of the substrate, wherein a first portion of one of the first spacer regions is positioned between the middle dielectric layer and at least a portion of the first S/D region of the first layer positioned nearest to the middle dielectric layer, a second portion of the one of the first spacer regions is positioned between the middle dielectric layer and at least a portion of the second S/D region of the first layer positioned nearest to the middle dielectric layer, a first portion of individual of the other first spacer regions positioned adjacent to at least a portion of the first S/D region of two of the first layers, and a second portion of individual of the other first spacer regions positioned adjacent to at least a portion of the second S/D region of two of the first layers; and
a plurality of second spacer regions stacked vertically with respect to the surface of the substrate, wherein a first portion of one of the second spacer regions is positioned between the middle dielectric layer and at least a portion of the third S/D region of the second layer positioned nearest to the middle dielectric layer, a second portion of the one of the second spacer regions is positioned between the middle dielectric layer and at least a portion of the fourth S/D region of the second layer positioned nearest to the middle dielectric layer, a first portion of individual of the other second spacer regions positioned adjacent to at least a portion of the third S/D region of two of the second layers, and a second portion of individual of the other second spacer regions positioned adjacent to at least a portion of the second S/D region of two of the second layers.

3. The apparatus of claim 2, wherein the first spacer regions comprise:
silicon and oxygen;
silicon, oxygen, and one of carbon, fluorine, and hydrogen; or
silicon and nitrogen.

4. The apparatus of claim 1, further comprising a contact region comprising the first metal, the second metal, or another metal, individual of the first S/D regions of the first layers comprising an end positioned adjacent to the contact region.

5. The apparatus of claim 4, wherein the contact region comprises tungsten, cobalt, titanium, gold, aluminum, molybdenum, chromium, or nickel.

6. The apparatus of any claim 1, further comprising a gate contact region comprising the first metal, the second metal, or another metal, the gate contact region positioned adjacent to the first gate region positioned furthest away from the middle dielectric layer.

7. The apparatus of claim 1, wherein the non-crystalline silicon of the first layers comprises amorphous silicon or polycrystalline silicon.

8. The apparatus of claim 1, wherein the n-type dopant is phosphorous, arsenic, or antimony.

9. The apparatus of claim 1, wherein the p-type dopant is boron or gallium.

10. The apparatus of claim 1, wherein the middle dielectric layer comprises:
silicon and oxygen;
silicon, oxygen, and one of carbon, fluorine, or hydrogen; or
silicon and nitrogen.

11. The apparatus of claim 1, wherein the first metal comprises hafnium, zirconium, titanium, tantalum, aluminum.

12. The apparatus of claim 11, the first metal further comprises carbon.

13. The apparatus of claim 1, wherein the first metal comprises ruthenium, palladium, platinum, cobalt, or nickel.

14. The apparatus of claim 1, wherein the first gate dielectric layers comprise:
hafnium and oxygen;
hafnium, oxygen, and silicon;
lanthanum and oxygen;
lanthanum, oxygen, and aluminum;
zirconium and oxygen;
zirconium, oxygen, and silicon;
tantalum and oxygen;
titanium and oxygen;
barium, strontium, titanium, and oxygen;
barium, titanium, and oxygen;
strontium, titanium, and oxygen;
yttrium and oxygen;
aluminum and oxygen;
lead, scandium, tantalum, and oxygen; or
lead, zinc, and niobium.

15. The apparatus of claim 1, wherein the apparatus is an integrated circuit component.

16. The apparatus of claim 15, further comprising a printed circuit board, the integrated circuit component attached to the printed circuit board.

17. An apparatus comprising:
a substrate comprising silicon;
a plurality of first layers stacked vertically with respect to a surface of the substrate, individual of the first layers comprising non-crystalline silicon and an n-type dopant;
a plurality of second layers stacked vertically with respect to the surface of the substrate, individual of the second layers comprising silicon and a p-type dopant; and
a middle dielectric layer positioned between the plurality of first layers and the plurality of second layers.

18. The apparatus of claim 17, further comprising:
a plurality of first spacer regions stacked vertically with respect to the surface of the substrate, wherein a first spacer region is positioned between the middle dielectric layer and a first layer positioned nearest to the middle dielectric layer, the other first spacer regions positioned adjacent to two of the first layers; and
a plurality of second spacer regions stacked vertically with respect to the surface of the substrate, wherein a second spacer regions is positioned between the middle dielectric layer and a second layer positioned nearest to the middle dielectric layer, the other second spacer regions positioned adjacent to two of the second layers.

19. A method comprising:
forming a plurality of first layers above a substrate, wherein the first layers are stacked vertically relative to a surface of the substate, individual of the first layers comprising silicon, individual of the first layers comprising a first region, a second region, and a third region, the first region positioned laterally between the second and third regions, the second and third regions comprising a p-type dopant;
forming a middle dielectric layer over the plurality of first layers;
depositing a plurality of second layers and a plurality of spacer regions on or above the middle dielectric layer, a bottommost spacer region deposited on the middle dielectric layer, individual of the second layers deposited on one of the spacer regions, individual of the second layers comprising non-crystalline silicon, individual of the second layers comprising a first region, a second region, and a third region, the first region positioned laterally between the second and third regions, the second and third regions comprising an n-type dopant;
etching the first layers, the middle dielectric layer, the spacer regions, and the second layers to form a pillar;
forming a plurality of first gate regions, individual of the first regions of the first layers positioned vertically between two first gate regions; and
forming a plurality of second gate regions, individual of the first regions of the second layers positioned vertically between two second gate regions.

20. The method of claim 19, further comprising:
forming a first contact region positioned adjacent to an end of individual of the first regions of the first layers; and
forming a second contact region positioned adjacent to an end of individual of the second regions of the first layers.
